(19) United States
(12) Patent Application Publication
(10) Pub. No.: US 2008/0206028 A1
(43) Pub. Date: Aug. 28, 2008

(54) Pod cover removing-installing apparatus

(76) Inventor: Tatsuhiko Nagata, Tokyo (JP)

Correspondence Address: STAAS & HALSEY LLP, SUITE 700, 1201 NEW YORK AVENUE, N.W., WASHINGTON, DC, 20005, US

(21) Appl. No.: 12/010,319

(22) Filed: Jan. 23, 2008

Related U.S. Application Data
(63) Continuation-in-part of application No. 11/389,105, filed on Mar. 27, 2006, now Pat. No. 7,344,349.
Application No. 11/389,105 is a division of application No. 09/997,265, filed on Nov. 30, 2001, now Pat. No. 7,112,027.

(51) Int. Cl. H01L 21/67

(52) U.S. Cl. 414/411

(57) ABSTRACT

A pod cover removing-installing apparatus is provided. The apparatus removes and installs a cover for an opening of a pod, an inside of which is kept extremely clean, by causing the cover to engage a door for an opening of a high cleanliness room, while maintaining high cleanliness of the pod and the room by closely attaching circumferences of the two openings. The apparatus includes a movable pod table and a linking pin provided on the pod table. The movable pod table has the pod installed thereon. The linking pin is substantially vertically aligned with respect to a moving direction of the pod table and comes in contact with a fixed side which is substantially vertically aligned with respect to the moving direction of the pod table. The fixed side is provided in a V-section groove provided on a bottom of the pod.

### CROSS-REFERENCE TO RELATED APPLICATIONS

The instant application is a continuation-in-part of U.S. patent application Ser. No. 11/389,105, filed Mar. 27, 2006, now pending, which is a divisional of U.S. patent application Ser. No. 09/997,265, filed Nov. 30, 2001, now U.S. Pat. No. 7,11,027, which are incorporated by reference herein.

### BACKGROUND OF THE INVENTION

1. Field of the Invention

The present invention relates to a pod cover removing-installing apparatus for a pod which contains and transfers thin substrates such as semiconductor wafers from one space to another space while maintaining the cleanliness of both spaces.

2. Related Art

FIG. 21 shows an example of a conventional pod cover removing-installing apparatus.

This conventional pod cover removing-installing apparatus 100 is provided with a diaphragm 101 which partitions off a high clean space A and a low clean space B, an opening 102 formed in the diaphragm 101 that serves as a passage between the high clean space A and the low clean space B, a door 103 which opens and closes the opening 102 of the diaphragm 101, a latch mechanism 104 that latches the cover 203 of the pod 200 with two positioning pins 104a, 104b and two T-shaped keys 104c, 104d provided in the door 103, and a table 105 provided in the low clean space B for mounting the pod 200, which has three positioning pins 105a, 105b, 105c and one lock key 105d.

The pod 200 is a container with an extremely clean internal space C for containing a plurality of semiconductor wafers (25 wafers, for example).

This pod 200 is provided with a main container body 201, an opening 202 provided on one side of the main container body 201, a cover 203 for opening and closing the opening 202, the cover 203 having pin holes 204a, 204b for engaging the positioning pins 104a, 104b, and key holes 204c, 204d for engaging T-shaped keys 104c, 104d, and a bottom 205 having grooves 205a, 205b, 205c possessing a V-shaped section for engaging the positioning pins 105a, 105b, 105c, and a key hole 205d for engaging the lock key 105d.

When the pod 200 is placed on the table 105, the three positioning pins 105a, 105b, 105c engage the V-shaped section-possessing grooves 205a, 205b, 205c. In this instance, switching on a lock button, not shown in the drawing, causes the lock key 105d to move upward, become angled, and engage the key hole 205d. Then, the table 105 moves toward the diaphragm 101 for a prescribed distance (about 30 mm, for example), thereby causing the pod 200 to become attached to the diaphragm 101. A sealing material such as an O-ring, not shown in the figure, is provided along the circumference of the opening 102 of the diaphragm 101 and the opening 202 of the pod 200, to ensure close attachment of the openings and maintain cleanliness.

The movement of the table 105 causes the cover 203 of the pod 200 to become closely attached to the door 203, whereby the positioning pins 104a, 104b engage the pin holes 204a, 204b of the cover 203 and the T-shaped keys 104c, 104d engage the key holes 204c, 204d. Thereafter, the T-shaped keys 104c, 104d are rotated 90 degrees by a rotary actuator or the like, not shown in the figure, whereby nails 204e to 204h are pulled in to release the lock between the container main body 201 and the cover 203.

Then, the door 103 is pulled into the space A (arrow D1) and caused to descend (arrow D2) by a drive mechanism, not shown in the figure, whereby the internal space C of the pod 200 and the internal space A of the partition board 101 are brought into communication while maintaining cleanliness.

In the conventional technology mentioned above, the pod 200 is made from a resin by molding. Because the formed article may be distorted depending on molding conditions or temperatures, the positioning pins 104a, 104b, the pin holes 204a, 204b of the cover 203, and the key holes 204c, 204d are tapered to ensure a smooth removing-installing operation.

However, when wafers with a large diameter (exceeding 300 mm) are placed in the pod 200, a very stringent standard is necessary to secure an allowable distortion error of +/−0.5 mm. For this reason, significant difficulties may be encountered for performing the above operation in a stable manner. The following countermeasures are considered to overcome this problem.

(A) One method is to precisely fabricate and adjust each pair of the main container body 201 and cover 203, and assemble the apparatus using such a pair of the main container body 201 and cover 203. However, this method requires readjustment of the apparatus when another pod is used.

(B) Another method is to absorb a deviation between the main container body 201 and the cover 203 by designing the main container body 201 to be slightly movable. This method is effective for a small distortion, but ineffective for a large distortion. For example, even if there are no problems when the apparatus is new, distortions will be produced in two or three years after fabrication and the apparatus may not operate smoothly as time goes by.

An object of the present invention is to provide a pod cover removing-installing apparatus for a pod which can open and close any cover for a variety of pods made, according to the SEMI standard, by a variety of manufacturers. These pods can satisfy an allowable distortion error and are capable of being normally operated even if conditions such as temperature, humidity, and use for such a variety of pods change, and the covers of these pods can be removed and installed without causing it to collide with any one of the parts of the pods.

### SUMMARY OF THE INVENTION

In an aspect of the present invention, a pod cover removing-installing apparatus is provided. The apparatus removes and installs a cover (603) for an opening of a pod (600), an inside of which is kept extremely clean, by causing the cover to engage a door for an opening of a high cleanliness room, while maintaining high cleanliness of the pod and the room by closely attaching circumferences of the two openings. The apparatus includes a movable pod table (15) and a linking pin (15a-15c) provided on the pod table. The movable pod table has the pod installed thereon. The linking pin is substantially vertically aligned with respect to a moving direction (M) of the pod table and comes in contact with a fixed side (605a-1, 605b-1 and 605c-1) which is substantially vertically aligned with respect to the moving direction of the pod table. The fixed side is provided in a V-section groove (605a-605c) provided on a bottom of the pod.

In another aspect of the present invention, a pod cover removing-installing apparatus is provided, in which the moving direction (M) of the pod table (15) is set in a horizontal direction, an axis of the linking pin (15a-15c) is vertically aligned with the horizontal direction, the fixed side (605a-1, 605b-1 and 605c-1) is a vertical inner wall provided in a recessed portion (605a-2, 605b-2 and 605c-2) of the V-section groove (605a-605c), and the linking pin engages with the vertical inner wall.

In still another aspect of the present invention, a pod cover removing-installing apparatus is provided, in which the linking pin (15a-15c) has a first flat surface (15a-7) on an end portion thereof, the recessed portion (605a-2, 605b-2 and 605c-2) has a second flat surface (605a-7) on a bottom portion thereof, and the first flat surface and the second flat surface come into surface contact with each other so as to determine a vertical position of the pod.

In yet another aspect of the present invention, a pod cover removing-opening apparatus further including a detector is provided. The detector detects an occurrence of surface contact between the first flat surface and the second flat surface

In a further aspect of the present invention, a pod cover removing-installing apparatus is provided, in which the linking pin has an abutting portion (811-1, 915a-8) that comes into contact with a slope (205a-6, 605a-6) of the V-section groove (205a, 605a) so as to determine a vertical position of the pod (200).

In a still further aspect of the present invention, a pod cover removing-installing apparatus is provided, in which the moving direction (M) of the pod table (15) is set in a horizontal direction, the linking pin (15a-15c) has a guide portion (15a-6) on an end portion thereof, the guide portion being sectionally configured to be tapered, and the guide portion allows the fixed side (605a-1, 605b-1 and 605c-1) to be guided into contact with the linking pin.

In a yet further aspect of the present invention, a pod cover removing-installing apparatus is provided, in which the moving direction (M) of the pod table (915) is set in a horizontal direction, the linking pin (915a) has a guide portion (915a-6) on an end portion thereof, the guide portion being sectionally configured to be circular, and the guide portion allows the fixed side (605a-1) to come into contact with the linking pin.

In another aspect of the present invention, a pod cover removing-installing apparatus is provided, which further includes a guide portion (811-1), a base member (811) and a biasing member (816). The guide portion abuts with a slope (605a-6) of the V-section groove (605a) so as to guide the fixed side (606a-1) to the linking pin (815a). The base member supports the linking pin movably in an axial direction thereof. The biasing member biases the linking pin. In addition, the slope (605a-6) of the V-section groove thrusts the linking pin into the base member while the guide portion is guiding the fixed side to the linking pin. The biasing member urges the linking pin to project from the base member when the guide portion finishes guiding the fixed side to the linking pin.

In still another aspect of the present invention, a pod cover removing-installing apparatus is provided, which further includes a detector (818, 818-1 and 818-2) that detects the projection of the linking pin (815a) from the base member (811).

In yet another aspect of the present invention, a pod cover removing-installing apparatus is provided, in which the guide portion (811-1) is an abutting portion (811-1) that abuts with the slope (605a-6) of the V-shaped groove (605a) so as to determine a vertical position of the pod (600) after the guide portion finishes guiding the fixed side (605a-1) to the linking pin (815a).

In a further aspect of the present invention, a pod (600) with high cleanliness having a cover (603) for an opening is provided. The cover is removed and installed by a pod cover removing-installing apparatus when the cover is engaged with a door for an opening of a room with high cleanliness, while high cleanliness of the pod and the room is maintained by closely attaching circumferences of the two openings. The pod includes a V-section groove (605a-605c) provided on a bottom of the pod. The V-section groove has a fixed side (605a-1, 605b-1 and 605c-1) substantially vertically aligned with respect to a moving direction (M) of a movable table (15) of the pod cover removing-installing apparatus. The fixed side comes into contact with a linking pin (15a-15c) that is substantially vertically aligned with respect to the moving direction and provided on the movable pod table.

In a still further aspect of the present invention, a pod is provided, in which the moving direction (M) of the movable pod table (15) is set in a horizontal direction, the fixed side (605a-1, 605b-1 and 605c-1) is a vertical inner wall provided in a recessed portion (605a-2, 605b-2 and 605c-2) of the V-section groove (605a-605c), and the vertical inner wall engages with the linking pin (15a-15c).

In a yet further aspect of the present invention, a pod is provided, in which the recessed portion (605a-2, 605b-2 and 605c-2) has a first flat surface (605a-7) on a bottom portion thereof, the linking pin (15a-15c) has a second flat surface (15a-7) on an end portion thereof, and the first flat surface and the second flat surface come into surface contact with each other so as to determine a vertical position of the pod.

In another aspect of the present invention, a system for removing and installing a cover of a pod is provided. The system includes a pod (600) that is internally kept clean and a cover removing-installing unit. The cover removing-installing unit removes and installs a cover (603) for an opening of the pod by causing the cover to engage a door for an opening of a high cleanliness room, while maintaining high cleanliness of the pod and the room by closely attaching circumferences of the two openings. The cover removing-installing unit includes a movable table (15) and a linking pin (15a-15c). The linking pin is substantially vertically aligned with respect to a moving direction (M) of the movable table and provided on the movable table. The pod has a fixed side (605a-1, 605b-1 and 605c-1) that is substantially vertically aligned with respect to the direction of the movable table and is provided in a V-section groove (605a-605c) provided on a bottom of the pod. The fixed side comes into contact with the linking pin.

### BRIEF DESCRIPTION OF THE DRAWINGS

FIG. 1 is a perspective view showing an outline of a first embodiment of the cover removing-installing apparatus for a pod of the present invention;

FIG. 2 is a front view of the first embodiment of the cover removing-installing apparatus for a pod of the present invention;

FIGS. 3(a) and 3(b) are enlarged views of the part III of FIG. 2 and show the fine adjustment mechanism for the pod cover removing-installing apparatus of the first embodiment;

FIGS. 4(a) and 4(b) are enlarged views of the part IV of FIG. 2 and show the centering mechanism for the pod cover removing-installing apparatus of the first embodiment;

FIG. 5 is a cross sectional view along the line V-V of FIG. 2 and shows the holding mechanism of the pod cover removing-installing apparatus of the first embodiment;

FIG. 6(a) is a perspective view and FIG. 6(b) is a cross sectional view along the line VI-VI of FIG. 2, showing an eccentric transmission mechanism for the pod cover removing-installing apparatus of the first embodiment;

FIG. 7 is a cross sectional view along the line VII-VII of FIG. 2 and shows the positioning securing means of the pod cover removing-installing apparatus of the first embodiment;

FIG. 8 is a block diagram showing a control means for the pod cover removing-installing apparatus of the first embodiment;

FIG. 9 is a flowchart showing an operational example (cover opening operation 1) for the pod cover removing-installing apparatus of the first embodiment;

FIG. 10 is a flowchart showing an operational example (cover opening operation 2) for the pod cover removing-installing apparatus of the first embodiment;

FIG. 11 is a flowchart showing an operational example (cover closing operation 1) for the pod cover removing-installing apparatus of the first embodiment;

FIG. 12 is a flowchart showing an operational example (cover opening operation 2) for the pod cover removing-installing apparatus of the first embodiment;

FIG. 13 is a front view showing the main part of a second embodiment of the cover removing-installing apparatus for a pod of the present invention;

FIGS. 14(a) and (b) are drawings showing the main part of the second embodiment of the pod cover removing-installing apparatus of the present invention, wherein FIG. 14(a) is a cross sectional view along the line A-A of FIG. 13 and FIG. 14(b) is a cross sectional view along the line B-B of FIG. 13;

FIGS. 15(a) and (b) are drawings showing the main part of the second embodiment of the pod cover removing-installing apparatus of the present invention, wherein FIG. 15(a) is a drawing viewed from the arrow E in FIG. 15(b) and FIG. 15(a) is a cross sectional view along the line C-C of FIG. 13;

FIGS. 16(a) and (b) are cross sectional views along the line D-D of FIG. 13 showing the main part of the second embodiment of the cover removing-installing apparatus for a pod of the present invention;

FIG. 17 shows a holding mechanism of the pod cover removing-installing apparatus according to the third embodiment;

FIGS. 18(a), (b), and (c) are drawings showing a positioning member of the pod cover removing-installing apparatus according to the fourth embodiment;

FIGS. 19(a), (b), (c), and (d) are drawings showing a table positioning member of the pod cover removing-installing apparatus according to the fifth embodiment;

FIGS. 20(a) and (b) are drawings showing a positioning member of the pod cover removing-installing apparatus according to the sixth embodiment;

FIG. 21 shows an example of a conventional pod cover removing-installing apparatus;

FIG. 22(a) is a partial sectional view showing a pod and table according to the fifth embodiment. FIG. 22(b) is a bottom view showing the pod;

FIGS. 23(a) and 23(b) are sectional views showing a V-section groove and a positioning pin according to the fifth embodiment, which are engaged with each other;

FIG. 24 is a sectional view showing a V-section groove of a pod engaging with a positioning pin of a cover removing-installing apparatus according to the seventh embodiment;

FIG. 25 is a sectional view showing a positioning pin of a cover removing-installing apparatus engaging with a V-section groove of a pod according to the seventh embodiment;

FIG. 26 is a sectional view showing a positioning pin of a cover removing-installing apparatus engaging with a V-section groove of a pod according to the eighth embodiment; and

FIG. 27 is a sectional view showing a positioning pin of a cover removing-installing apparatus engaging with a V-section groove of a pod according to the ninth embodiment.

### DETAILED DESCRIPTION OF THE INVENTION

The present invention will be described in more detail by way of preferred embodiments with reference to the attached drawings.

### a. First Embodiment

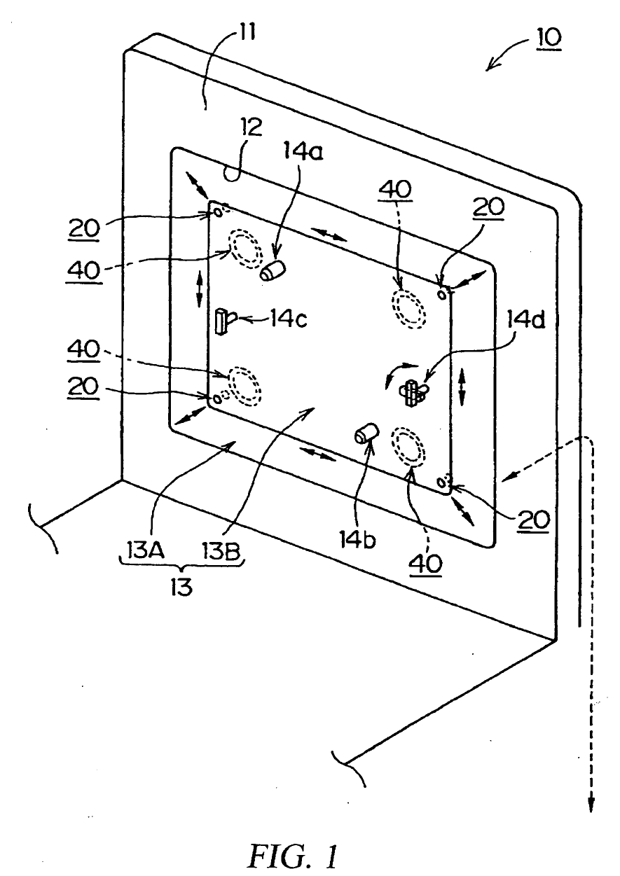

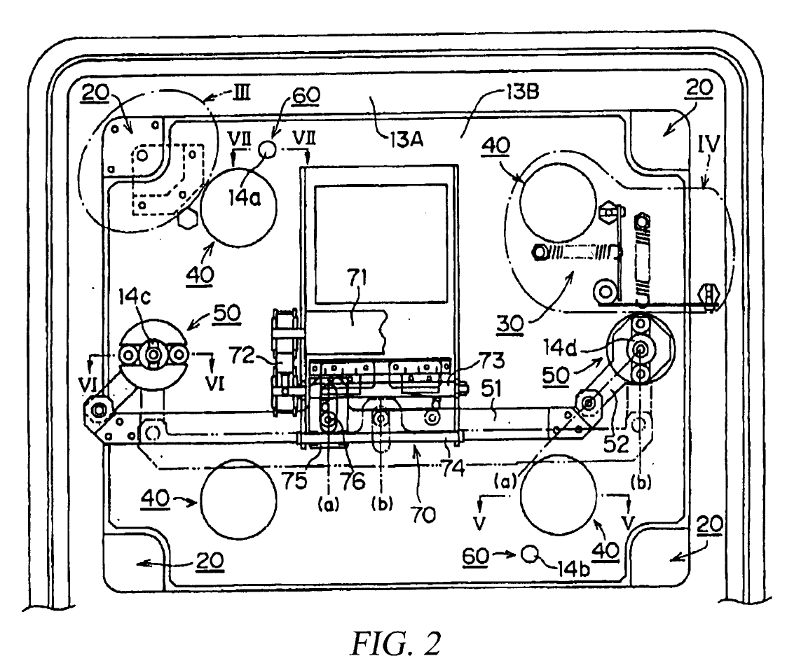

FIGS. 1 and 2 are drawings showing a first embodiment of the pod cover removing-installing apparatus of the present invention, wherein FIG. 1 is a perspective view showing an outline and FIG. 2 is a plan view of the apparatus.

This pod cover removing-installing apparatus is provided with a diaphragm 11, an opening 12, a door 13 which opens and closes the opening 12 of the diaphragm 11, two positioning pins 14a, 14b and two T-shaped keys 14c, 14d, a latch mechanism 14 which opens and closes a cover 203 of a pod 200, and the like.

In the first embodiment, the door 13 is provided with a base plate 13A and a position adjusting plate 13B movable in the direction vertical to the plane so that its position can be adjusted with respect to the base plate 13.

The door 13 is provided therein with four fine adjustment mechanisms 20, two centering mechanisms 30, four holding mechanisms 40, two eccentric transmission mechanisms 50, one positioning fixing means 60, and the like.

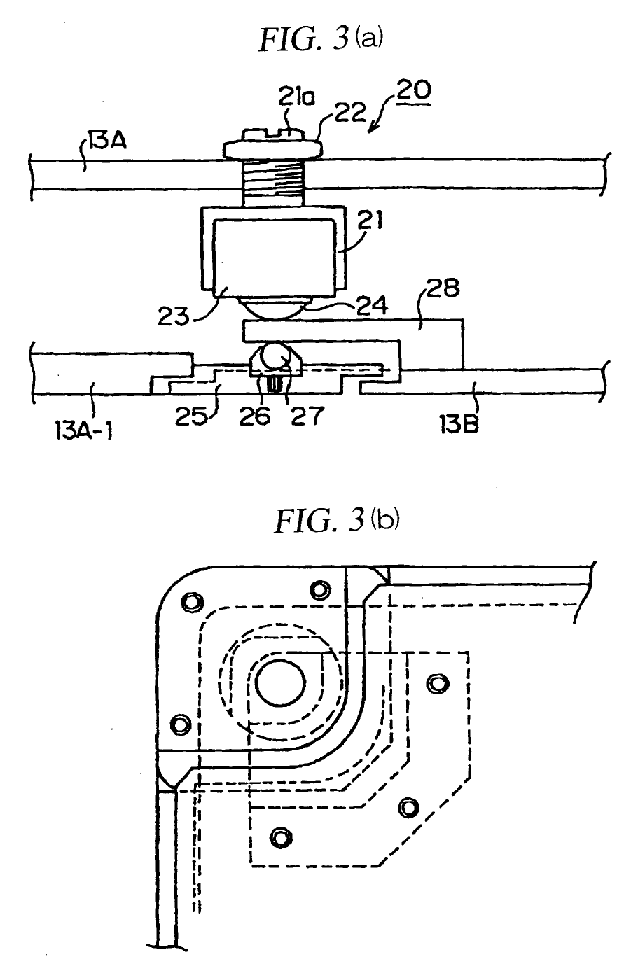

FIGS. 3(a) and 3(b) are enlarged views of the part III of FIG. 2 and show the fine adjustment mechanism for the pod cover removing-installing apparatus of the first embodiment.

The fine adjustment mechanism 20 supports the position adjusting plate 13B movable in the direction vertical to the plane and exactly adjusts the position of the positioning pins 14a and 14b. This fine adjustment mechanism 20 is provided in the four corners of the position adjusting plate 13B (see FIG. 1), each having a fixture 21 for fastening and securing the base plate 13A using a thread 21a, a female screw 22 for keeping the fixture 21 from loosening, a receiving member 23 of free bearings and the like inserted into the fixture 21, a ball 24 rotatively supported by the receiving member 23, an opposing plate 25 provided in the base plate frame 13A-1 on the opposing side, a receiving member 26 provided in the opposing plate 25, a ball 27 rotatively supported in the receiving member 26, a guide plate 28 provided on the side of position adjusting plate 13B and movably squeezed by the ball 24 and the ball 27.

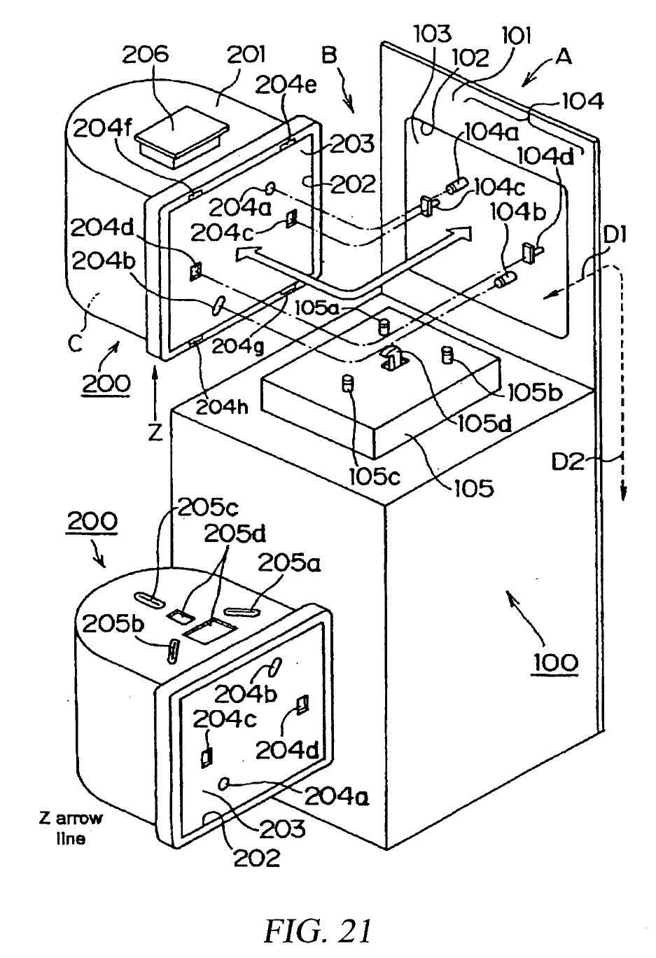

The fine adjustment mechanism 20 is designed so that in the initial state in which the positioning pins 14a, 14b engage the pin holes 204a, 204b of the pod 200 (see FIG. 21), tapered tips of the positioning pins 14a, 14b move a prescribed distance (e.g. 3 mm in every direction) vertically to the plane, while the tapered tips match the tapered pin holes 204a, 204b. For this reason, even if there is some error in the position of the pin holes 204a, 204b of the pod 200, the positioning pins 14a, 14b can easily engage these pin holes without colliding.

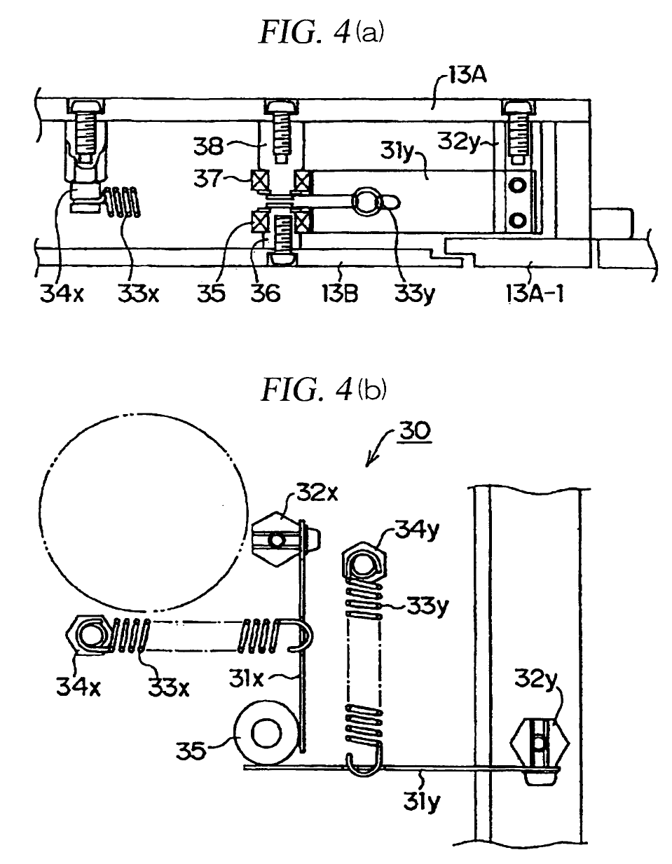

FIGS. 4(a) and 4(b) are enlarged views of the part IV of FIG. 2 and show the centering mechanism for the pod cover removing-installing apparatus of the first embodiment.

The centering mechanism 30 is a mechanism for causing the position adjusting plate 13B to return to the center. The centering mechanism 30, consisting of two systems, one in the horizontal direction (x direction) and the other in the vertical direction (y direction), is provided with press boards 31x, 31y, securing members 32x, 32y for securing the press boards 31x, 31y in the base plate 13A, coil springs 33x, 33y for moving the press boards 31x, 31y to the center, securing members 34x, 34y for securing the other ends of the coil springs 33x, 33y to the base plate 13A, guide pieces 35, 37 which come into contact with the press boards 31x, 31y, securing members 36, 38 for securing the guide pieces 35, 37 in the position adjusting plate 13B and base plate 13A, and the like.

The press board 31x aligns the guide pieces 35, 37 on a straight line in the X direction. In the same manner, the press board 31y aligns the guide pieces 35, 37 on a straight line in the Y direction. The position adjusting plate 13B is centered by these actions.

Although omitted from FIG. 2, a mechanism which is the same but symmetrical with the mechanism shown in the upper right side is provided in the upper left side of the FIG. 2.

Because the position adjusting plate 13B can move vertical to the plane with respect to the base plate 13A by means of the fine adjustment mechanism 20, the centering mechanism 30 always causes the position adjusting plate 13B to be positioned in the previously determined center position (the engaging position without an error) in the initial state in which the positioning pins 14a, 14b engage the pin holes 204a, 204b of the pod 200 (see FIG. 21).

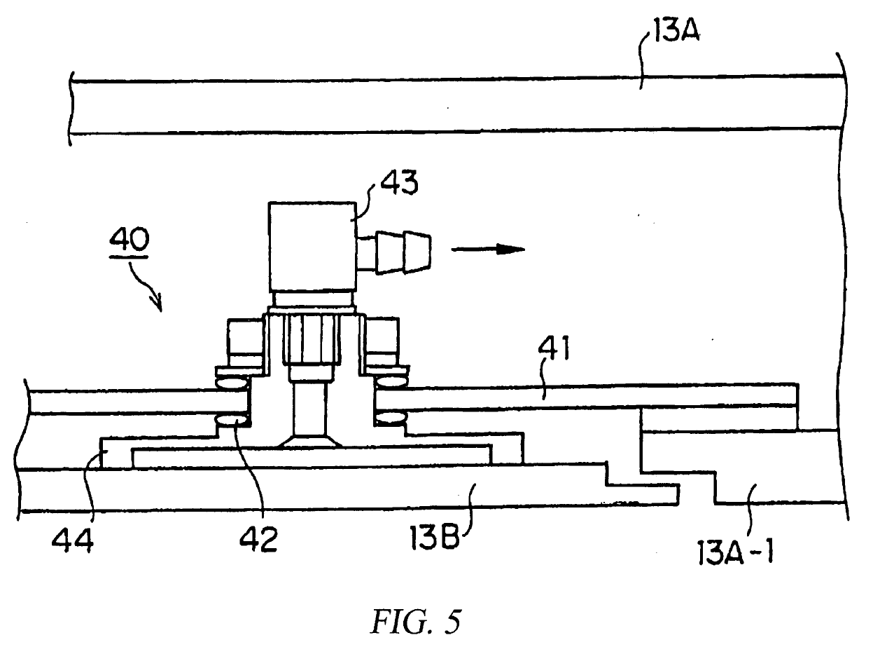

FIG. 5 is a cross sectional view along the line V-V of FIG. 2 and shows the holding mechanism of the pod cover removing-installing apparatus of the first embodiment.

The holding mechanism 40 holds the position adjusting plate 13B to the cover 203 of the pod 200 at the position where the positioning pins 14a, 14b engage. The holding mechanism 40 has a securing plate 41 provided in a base plate frame 13A-1, a joint 43 connected with this securing plate 41 through the O-ring 42, having a nozzle (not shown in the figure) connected to a vacuum pressure source, and an absorption pad 44 provided in the joint 43 which is capable of being attached to the position adjusting plate 13B.

Because the position adjusting plate 13B can move vertical to the plane with respect to the base plate 13A by means of the fine adjustment mechanism 20, the holding mechanism 40 can hold the positioning pins 14a, 14b to engage the pin holes 204a, 204b of the pod 200 (see FIG. 21). This structure ensures that the container maintains the same position as the position before removal when the cover 203 has been once removed and returned thereafter. Therefore, the cover can be closed without impediment.

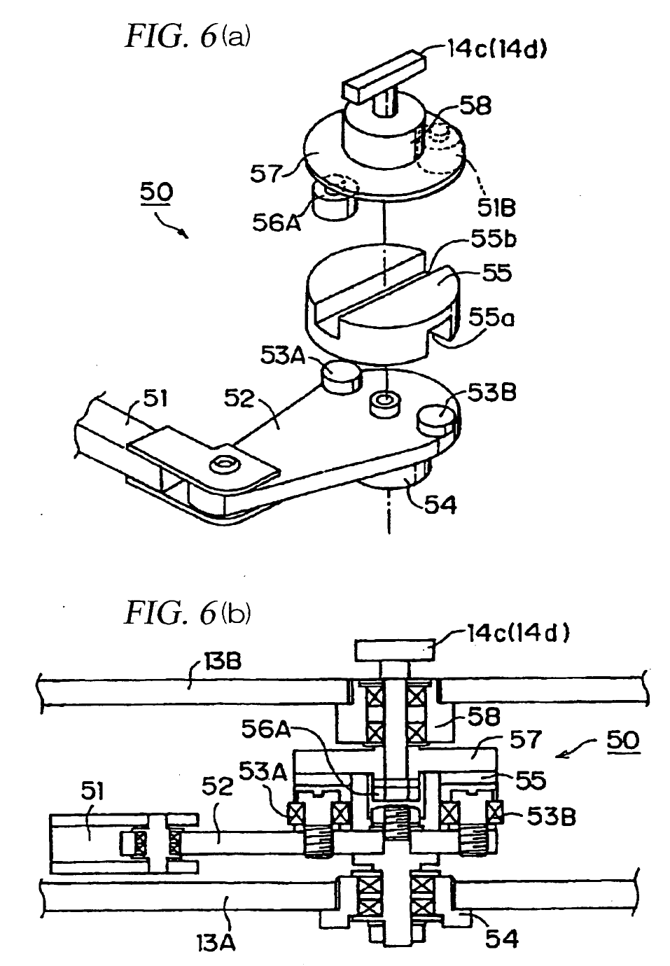

FIG. 6(a) is a perspective view and FIG. 6(b) is a cross sectional view along the line VI-VI of FIG. 2, showing an eccentric transmission mechanism for the pod cover removing-installing apparatus of the first embodiment.

The T-shaped key 14c (14d) is provided in a prescribed position of the position adjusting plate 13B to engage the key hole 204c (204d) of the cover 203 to lock the cover 203, and driven by a lock drive mechanism 70 (see FIG. 2). This lock drive mechanism 70 is provided on the side of the base plate 13A and rotates in either direction around the axis of the T-shaped key 14c (14d) to perform locking or unlocking movements.

Because it is desirable to make the position adjusting plate 13B light for ease of movement, the lock drive mechanism 70 and the like are preferably installed on the base plate 13A. For this reason, an eccentric transmission mechanism 50 is provided to transmit a driving force from the lock drive mechanism 70 to the T-shaped key 14c (14d).

This eccentric transmission mechanism 50 allows a deflection of the base plate 13A and position adjusting plate 13B in the direction vertical to the plane and transmits a rotational force of the lock drive mechanism 70 to the T-shaped key (locking member) 14c (14d).

As shown in FIGS. 6(a) and 6(b), the eccentric transmission mechanism 50 has a driving lever 51 connected to the lock drive mechanism 70, a rotation lever 52 rotatively connected to the driving lever 51, a bearing 54 supporting the rotation lever 52 on the base plate 13A in a freely rotative manner, transmission rollers 53A, 53B provided on the rotation lever 52, a slide disc 55 having grooves 55a, 55b orthogonally provided on both sides, into which the transmission rollers 53A, 53B and transmission rollers 56A, 56B are respectively inserted, a rotation board 57 provided on the same axis with the T-shaped key 14c (14d), a bearing 58 having the transmission rollers 56A, 56B provided therein and supporting the axis of the rotation board 57 and the T-shaped key 14c (14d) on the position adjusting plate 13B in a freely rotative manner, and the like.

The eccentric transmission mechanism 50 transmits a rotational force of the lock drive mechanism 70 to the T-shaped key 14c (14d), even if the position adjusting plate 13B moves from its original position within a movable range in the direction vertical to the plane.

Here, as shown in FIG. 2, the lock drive mechanism 70 is provided with a motor 71, a drive screw 73 to which the rotation of the motor 71 is transmitted by a belt 72, a slide axis 74 arranged in parallel with the drive screw 73, a moving block 75 freely slidably supported in the slide axis 74 and driven by a drive screw 73, a bearing 76 secured on a moving block 75 and engaging a long hole in the transmission lever 51, and the like.

When the bearing 76 is in the position (a), the rotation lever 52 is in the position (a). When the bearing 76 moves to the right and comes to the position (b), the rotation lever 52 rotates. This causes the transmission lever 51 to move that distance and to descend to the point indicated by a chain line connected by two dots. Because the bearing 76 is secured on the moving block 75, the horizontal level of the position (b) remains the same as that of the position (a). Because of this, a deviation of the engaging position of the transmission lever 51 and the bearing 76 is absorbed by the long hole of the transmission lever 51.

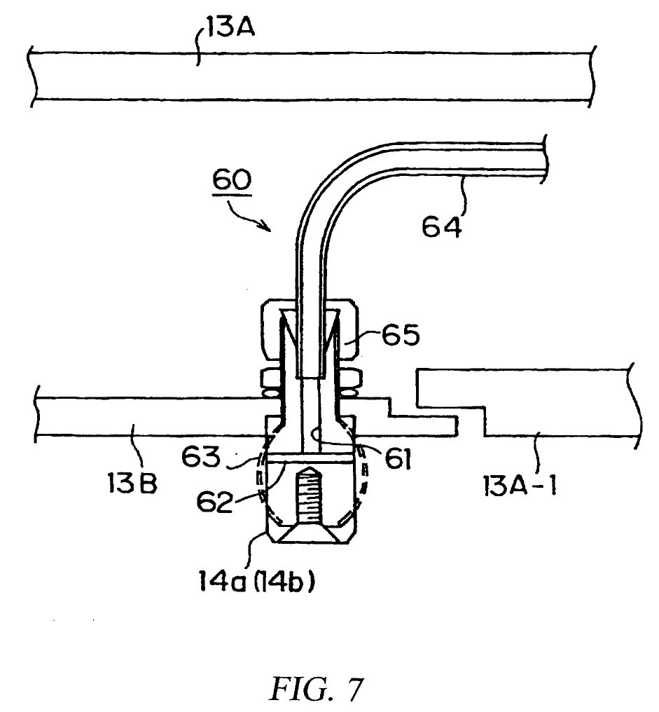

FIG. 7 is a cross sectional view along the line VII-VII of FIG. 2 and shows the positioning securing means of the pod cover removing-installing apparatus of the first embodiment.

The position securing means 60 secures the positioning pins 14a, 14b in the pin holes 204a, 204b when the positioning pins 14a, 14b engage the pin holes (the parts to be engaged) 204a and 204b of the pod 200 and their positions are determined.

The position securing means 60 of this embodiment has a passage 61 provided in the axial direction of the positioning pin 14a (14b), a passage 62 provided in the vertical direction of the passage 61 and joining therewith, a stretch member 63 formed from rubber such as neoprene provided around the circumference of the positioning pin 14a (14b) and capable of stretching according to an increase or decrease in the internal pressure, a pipe 64 connected with the passage 61, a securing member 65 for securing the pipe 64 at the rear end of the positioning pin 14a (14b), and the like.

In this position securing means 60, pipe 64 is connected to a pneumatic circuit or a vacuum circuit, not shown in the figure, which causes the internal pressure of the passages 61, 62 to increase or decrease, thereby causing the stretch member 63 to expand or contract, causing the gap between the positioning pins 14a, 14b and the pin holes 204a, 204b to be filled out. The positioning pins 14a, 14b are secured in the position in this manner.

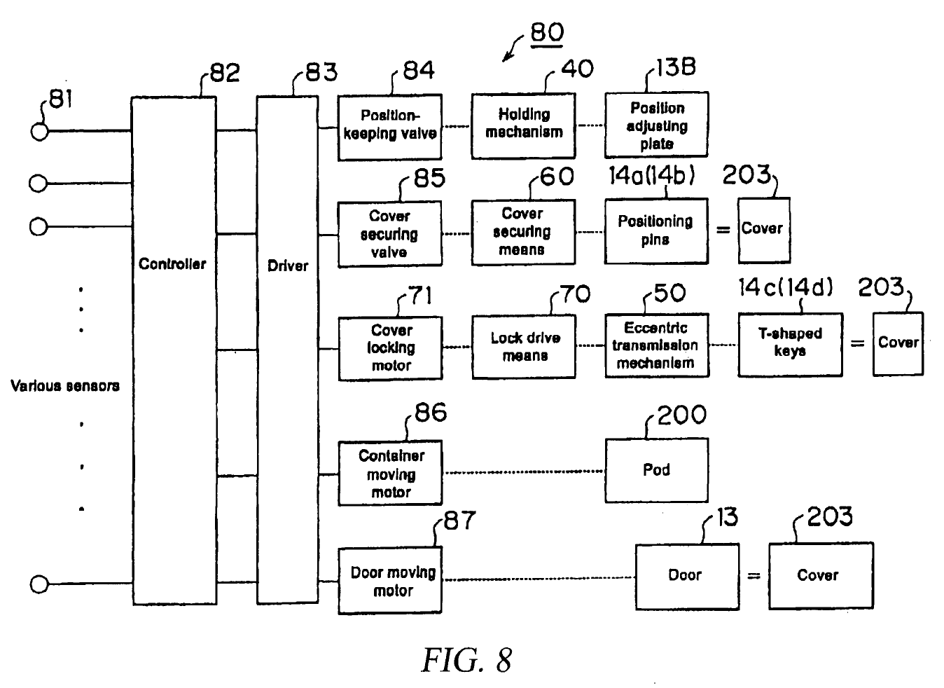

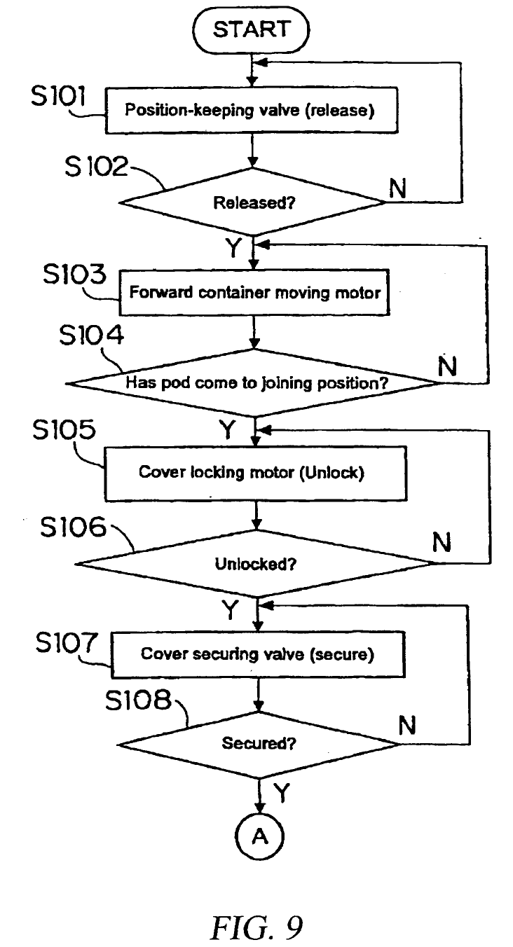

FIG. 8 is a block diagram showing a control means for the pod cover removing-installing apparatus of the first embodiment, and FIGS. 9-12 are flow charts showing operations of the cover removing-installing apparatus.

The control means 80 has various sensors 81 for detecting the positions and the like of each moving part, a controller 82 which produces various control signals to control each drive part, described later, based on the position detection signals from the sensors 81, a driver 83 for converting control signals from the controller 82 into drive signals conforming to each drive part, and a drive part driven based on the drive signals from the driver 83, including a position-keeping valve 84 which controls the flow of the air pressure to the holding mechanism 40, a cover securing valve 85 which controls the flow of the air pressure to a cover securing means 60, a cover locking motor 71 of a lock drive means 70, a container moving motor 86, a door moving motor 87, and the like.

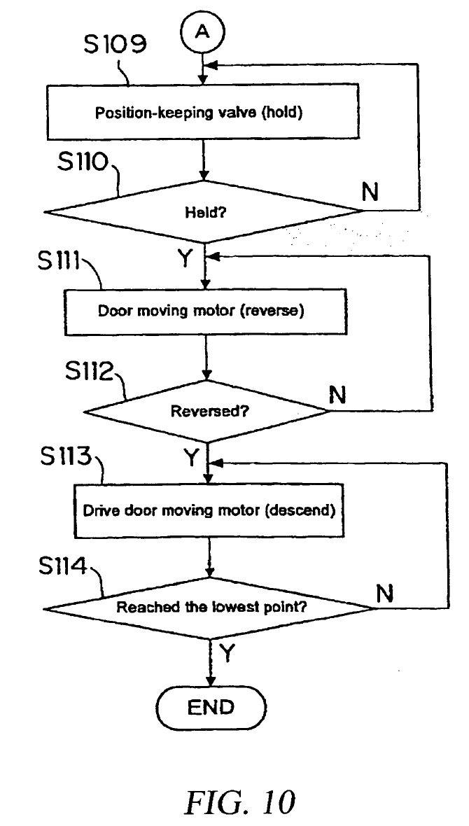

Next, the cover opening operation will be described referring to FIGS. 9 and 10.

The controller 82 drives the position-keeping valve 84 to the release side (Step 101, the step is hereinafter referred to as “S”) and, upon confirmation of release with a sensor (S102, YES), drives the container moving motor 86 to move the pod 200 forward (S103), then, upon confirmation that the pod 200 has come to the joining position (S104, YES), stops the container moving motor 86.

Because the holding mechanism 40 is canceled in this state by the position-keeping valve 84, the position adjusting plate 13B is not only free, but also has been moved to the center by the centering mechanism 30. When the pod 200 comes to the joining point, the position adjusting plate 13B can be moved by the fine adjustment mechanism 20, enabling the complete joining of the cover 203 of the pod 200 and the door 13 even though the pin holes 204a and 204b of the pod 200 deviate in the allowable range with respect to the positioning pins 14a, 14b.

Next, the cover locking motor 71 is driven to the unlock side (S105) and the T-shaped keys 14c and 14d are rotated to retract the nails 204e-204h of the cover 203. When the sensor confirms that the nails 204e-204h have been retracted (unlock) (S106, YES), the cover securing valve 85 is driven to the securing side (S107) to expand the stretch member 63 of the positioning pins 14a, 14b, confirming the securing of the pin holes 204a, 204b with the sensor (S108, YES).

In the final stage of the operation S107, even if there is a deviation between the positioning pins 14a, 14b and pin holes 204a, 204b, and the position adjusting plate 13B has been moved, the T-shaped keys 14c, 14d can rotate due to the eccentric transmission mechanism 50.

Moreover, accurate positioning is possible because the pin holes 204a, 204b are secured by expanding the stretch member 63 of the positioning pins 14a, 14b.

Next, as shown in FIG. 10, the position-keeping valve 84 is driven to the hold side (S109), confirming the holding with the sensor (S110, YES), and causing the door to reverse by driving the door moving motor 87 (S111). Upon confirmation that the door has reversed (S112, YES), the door moving motor 87 is further driven to move the door downward (S113). When the door has reached the lower limit (S114, YES), the operation to terminate the process is stopped.

In this state, the position-keeping valve 84 is driven to the hold side and holds the position of the position adjusting plate 13B in its original position in the later-described door closing operation. Therefore, the door does not collide with the opening 202 of the pod 200 when closed.

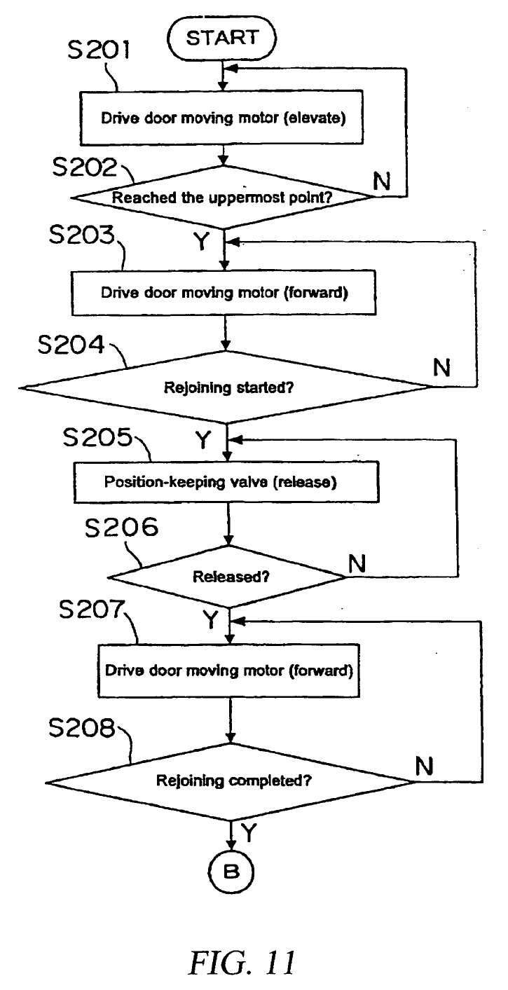

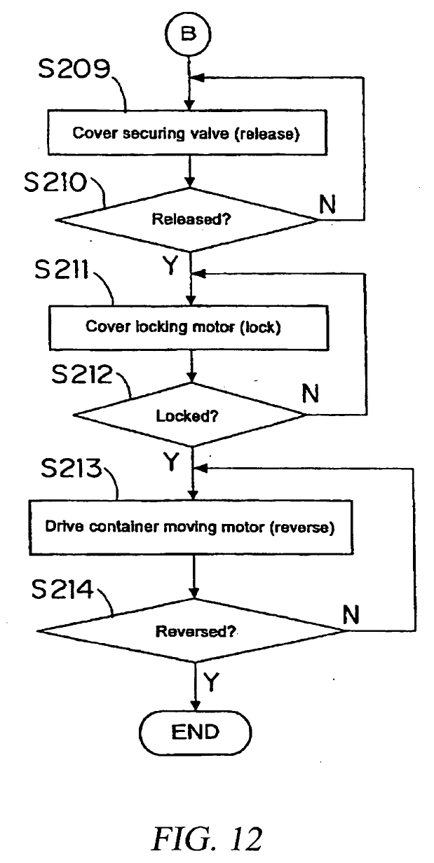

Next, the cover closing operation will be described referring to FIGS. 11 and 12.

Referring to FIG. 11, the controller 82 drives the door moving motor 87 to elevate (S201) to the upper limit point (S202, YES), then to go forward (S203) until it starts rejoining the pod 200. Upon confirmation of the initiation of rejoining by a sensor (S204, YES), the position-keeping valve 84 is driven to the release side (S205). Upon confirmation of the release by a sensor (S206, YES), the door moving motor 87 is driven forward (S207) until rejoining is complete, whereupon the door moving motor 87 is stopped and the rejoining with the pod 200 is confirmed by a sensor (S208).

Next, the cover securing valve 85 is driven to the release side (S209) to cause the stretch member 63 of the positioning pins 14a, 14b to become contracted. The release from the pin holes 204a, 204b is confirmed by a sensor (S210, YES). The cover locking motor 71 is driven to the lock side (S211) to rotate the T-shaped keys 104c, 104d and cause the nails 204e to 204h to protrude and lock the cover, which is confirmed by a sensor (S212, YES).

Finally, the container moving motor 86 is driven to move the pod 200 backward (S213). Upon confirmation by a sensor that the pod 200 has reversed (S104, YES), the container moving motor 86 is stopped to terminate the cover closing operation.

### b. Second Embodiment

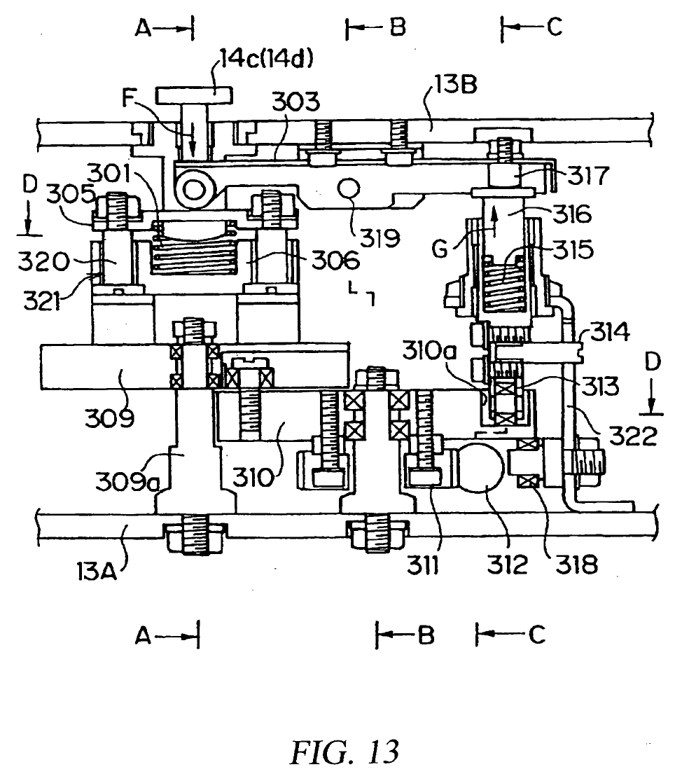

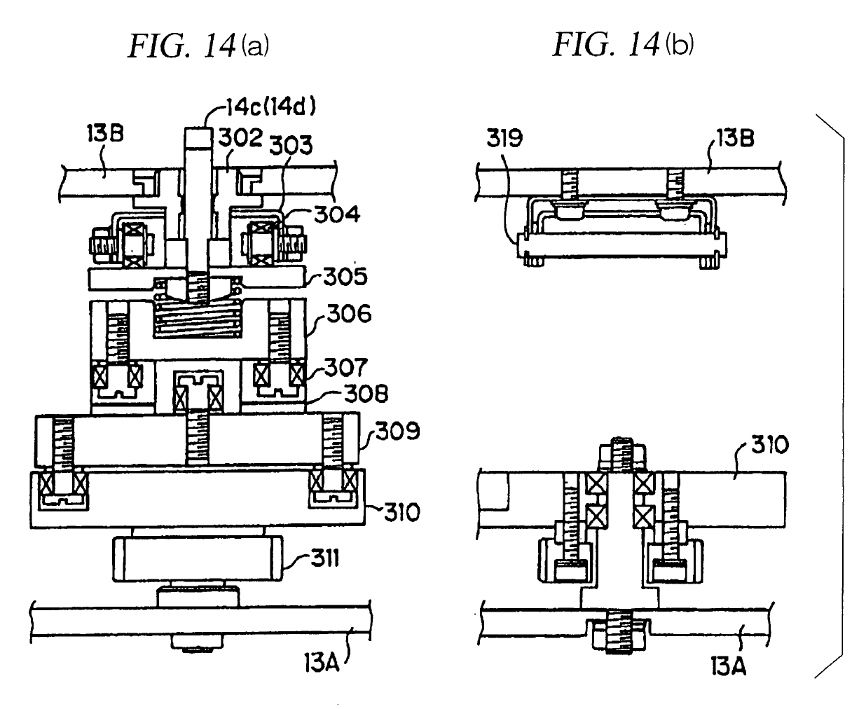

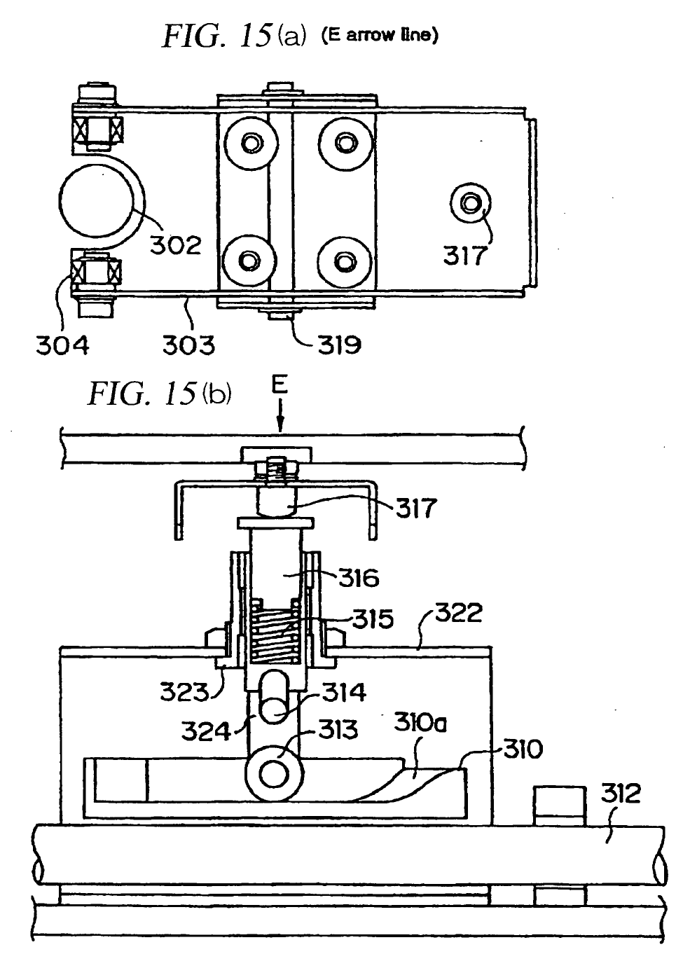

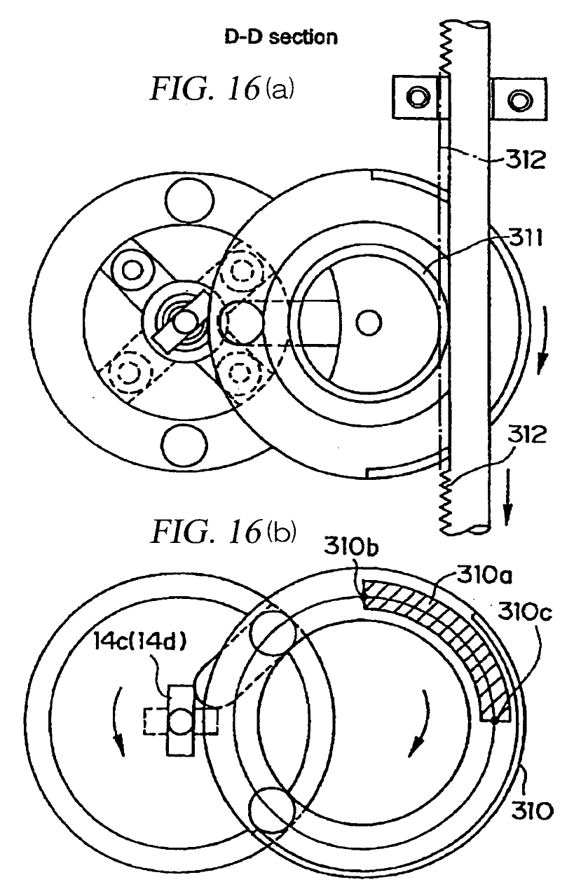

FIGS. 13-16(a) and (b) show the main parts of the pod cover removing-installing apparatus of the second embodiment, wherein FIG. 13 is a front view, FIG. 14(a) is a cross sectional view along the line A-A of FIG. 13, FIG. 14(b) is a cross sectional view along the line B-B of FIG. 13, FIG. 15(a) is a view from the direction of the arrow E of FIG. 15(b), FIG. 15(b) is a cross sectional view along the line C-C of FIG. 13, and FIGS. 16(a) and (b) are cross sectional views along the line D-D of FIG. 13.

The second embodiment of the pod cover removing-installing apparatus has, in addition to the structure of the first embodiment, a cover securing means which secures the cover 203 to the door 13 by retracting the lock pins 13a, 13b (by pulling down in FIG. 13) to the door 13 side.

A linear motion from a drive means, not shown in the drawing, to a rack 312 in FIG. 13 rotates a pinion gear 311 which engages the rack 312. A disc 310 is coaxially screwed to the pinion gear 311.

The disc 310 can rotate by 180 degrees, causing the T-shaped key 14c (14d) to rotate in the first 90-degree rotation and drawing the T-shaped key 14c (14d) to the direction of the arrow F in the next 90-degree rotation, thereby securing the cover 203 to the door 13 (the cover securing means).

A disc 309 is installed on an axis 309a in a freely rotative manner within an angle of 90 degrees. The axis 309a is screwed to the base plate 13A. A rotation from the disc 310 is transmitted to the disc 309 via a rotor (bearing) which is screwed to the groove formed on the bottom of the disc 309 and the top of the disc 310.

A rotating disc 306 is connected to the rotating disc 309 via a moving body 308 and a bearing 307, as shown in FIG. 14(a). The moving body 308 and the bearing 307 allow the rotation of the rotating disc 309 and the rotating disc 306, even if these deviate in any direction, i.e. up and down, right and left, or front and back.

Because not only the disc 305 is connected to the disc 306 via a support 320 and a bush 321 (FIG. 13), but also these parts are pressed together by a spring, the discs 305 and 306 rotate as an integral body.

The T-shaped key 14c (14d) is held on a holding base 302 movable in the axial direction. A push-down board 303 is connected to the holding base 302. The push-down board 303 is provided with a bearing 304 which maintains contact with the surface of the disc 305 while rotating. The disc 305 is pushed upward by the spring 301. The contact of the disc 305 with the holding base 302 ensures accurate determination of the position of the T-shaped key 14c (14d) in the axial direction.

The T-shaped key 14c (14d) rotates 90 degrees by a first 90-degree rotation of the disc 310 according to the above mechanism to complete a lock (or unlock) operation. In this instance, the rotation can be transmitted even if the rotating disc 309 and the rotating disc 306 deviate in any direction (up and down, right and left, or front and back) due to the existence of the moving body 308 and the bearing 307 (eccentric transmission mechanism).

As shown in FIGS. 13 and 15(a) and (b), a roller 318 is attached to a bracket 322 provided in the base plate 13A and comes into contact with the bottom of the disc 310 to prevent downward deflection of the disc 310.

A groove 310a is formed on the surface of the disc 310 as shown in FIG. 16(b). The bottom of the groove 310a slopes from the highest point 310b to the lowest point 310c. A bearing 313 enters the groove 310a and moves. The bearing 313 is installed on the bottom of the support member 324 which is provided in a freely slidable manner in the collar 323 installed on the bracket 322. The support member 324 has a cylindrical upper portion into which a support column 316 is inserted through a spring 315. A pin 314 is provided in the support member 324 to prevent its rotation. Because the pin 314 engages a long hole provided in the bracket 322, the support member 324 does not rotate even if it moves up and down.

A base seat 317 is screwed to a push-down board 303, with the bottom in contact with the top of the support member 316. The push-down board 303 is freely rotatively supported by a pin 319 and rotates counterclockwise in the FIG. 13 by a force pressing the base seat 317 upward (arrow G), thereby transmitting a push-down force (arrow F) to a bearing 304 which is provided on the other end.

Specifically, the push-down board 303 pushes down the T-shaped key 14c (14d) via the above-described mechanism in the next 90-degree rotation of the disc 310, whereby the cover 203 of the pod 200 may be secured to the door 13.

The second embodiment enables one driving force to cause rotation of the T-shaped key 14c (14d) and a pull-in operation of the T-shaped key 14c (14d) to secure the cover 203 to the door 13. In addition, the apparatus of the second embodiment is also provided with an eccentric transmission mechanism which allows deviation of the base plate 13A and the position adjusting plate 13B.

### c. Third Embodiment

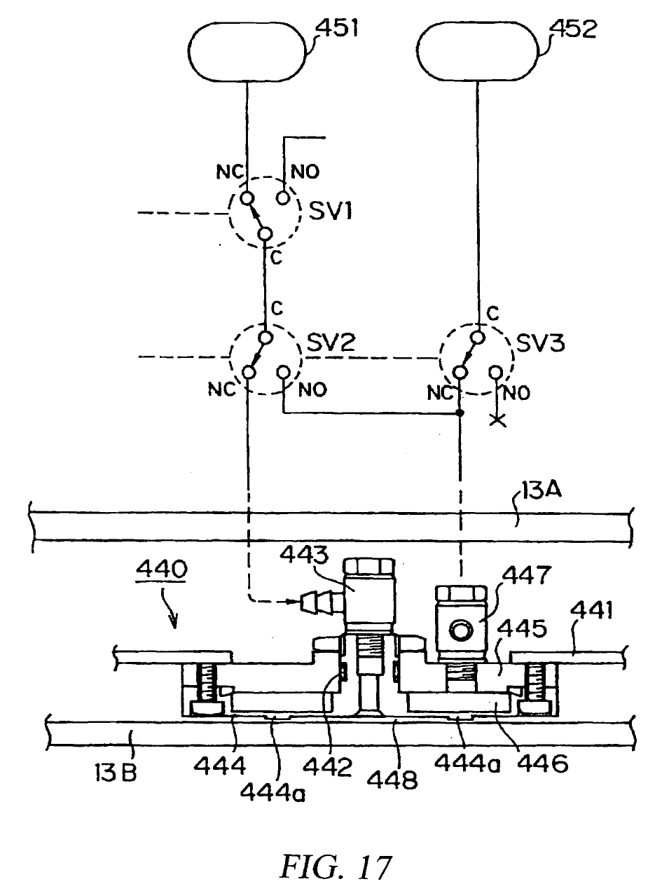

FIG. 17 shows a holding mechanism of the pod cover removing-installing apparatus according to a third embodiment.

A holding mechanism 440 has a securing plate 441 provided in a base plate frame (not shown), a base plate 445 provided on the securing plate 441, a main body 443 connected to the base plate 445 through an O-ring 442 and having a nozzle connected to a vacuum pressure source 451, an absorption pad 444 provided in the main body 443 and having a seat 444a to attach to the position adjusting plate 13B.

In this embodiment, a space 446 is formed between the absorption pad 444 and the base plate 445. The base plate 445 is provided with a nozzle 447 to connect the space 446 to an air pressure source 452.

A vacuum pressure source 451 is connected to the nozzle of the main body 443 through solenoid valves SV1 and SV2. The air pressure source 452 is connected to the nozzle 447 through a solenoid valve SV3.

The NC port of the solenoid valve SV1 spatially communicates with the vacuum pressure source 451, the NO port with the atmosphere, and the C port with the C port of the solenoid valve SV2. The NC port of the solenoid valve SV2 spatially communicates with the nozzle 443, and the NO port with NC port of the solenoid valve SV3. The C port of the solenoid valve SV3 spatially communicates with the air pressure source 452 and the NO port is shut off.

If the solenoid valves SV1, SV2, and SV3 are on the NC port side as shown in FIG. 17, with the vacuum pressure source 451 being evacuated and high pressure air being supplied from the air pressure source 452, the seat 444a of the adsorption pad 444 is pushed to the position adjusting plate 13B side by the pressure of the space 446 and the pressure of the space 448 inside the seat part 444a becomes negative, thereby accelerating the adherence of the adsorption pad 444.

On the other hand, if the solenoid valve SV1 is switched to the NO port side to open the space 448 to the atmosphere, then the solenoid valves SV2, SV3 are switched to the NO port side to open the space 446 to the atmosphere, the solenoid valve SV1 is switched to the NC port side, and the space 446 is adsorbed to accelerate release of the adsorption pad 444.

The third embodiment thus accelerates the adherence and release operations of the position adjusting plate 13B. In addition, because the seat part 444a separates from the position adjusting plate 13B during the release operation, the position adjusting plate 13B can move smoothly.

### d. Fourth Embodiment

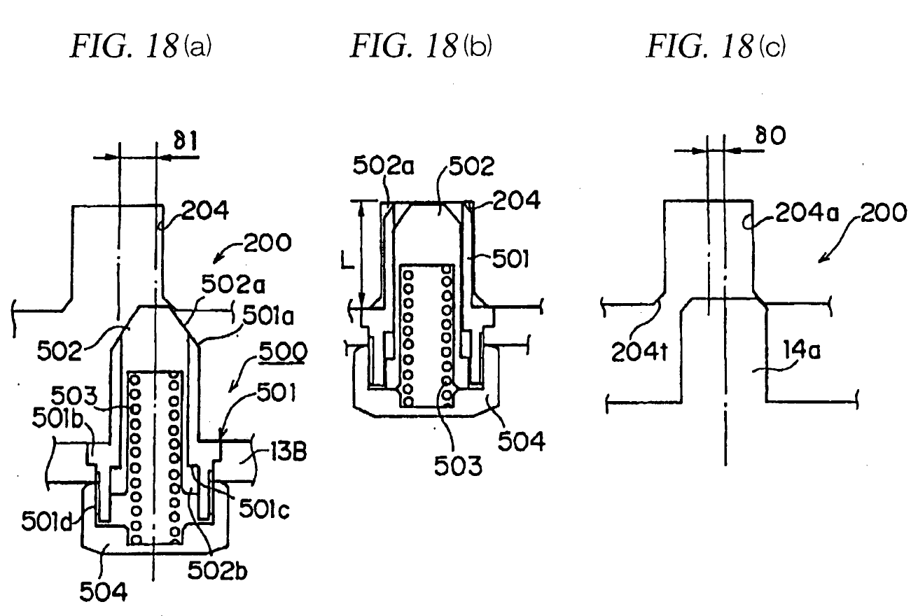

FIGS. 18(a), (b), and (c) show a positioning member of the pod cover removing-installing apparatus according to a fourth embodiment.

FIG. 18(c) shows a conventional system. In this system, if the deviation of the positioning pin 14a and the pin hole 204a becomes larger than δ0=1−1.5 mm, the positioning pin 14a may not smoothly enter the pin hole 204a depending on a taper 204t of the pin hole 204a on the pod 200 side.

A positioning member 500 of the fourth embodiment is provided with an outer casing 501 and an inner casing 502. The outer casing 501 is a cylinder having a taper 501a formed on the tip, a brim 501b formed on the outside, a step 501c formed inside, a thread part 501d formed in the back of the brim 501b, and the like, and is secured to the positioning plate 13B using the brim 501b.

The inner casing 502 is a cylinder inserted into the outer casing 501 and has a taper 502a having the same angle as the taper 501a of the outer casing 501, and a brim 502b formed on the outside of the end, wherein the brim 502b engages the step 501c to regulate the protrusion to a prescribed length.

A spring 503 inserted in the inner casing 502 pushes the inner casing 502 in the protrusion direction. A box nut 504 thrust in a thread 501d of the outer casing 501 secures the outer casing 501 to the position adjusting plate 13B and regulates the location of the end of the spring 503.

As shown in FIG. 18(a), because the outer casing 501 and the inner casing 502 are provided with a taper 501a or 502a having the same angle which is more acute than the conventional angle and a length longer than a conventional one, these are smoothly linked even if the deviation is in the range of δ1=3.0−3.5 mm.

As shown in FIG. 18(b), because the inner casing 502 escapes resisting the pushing force of the spring 503 after the completion of linking, the depth of the pin hole 204a may be the same depth (L=11 mm) as the pin hole of the conventional pod 200.

### e. Fifth Embodiment

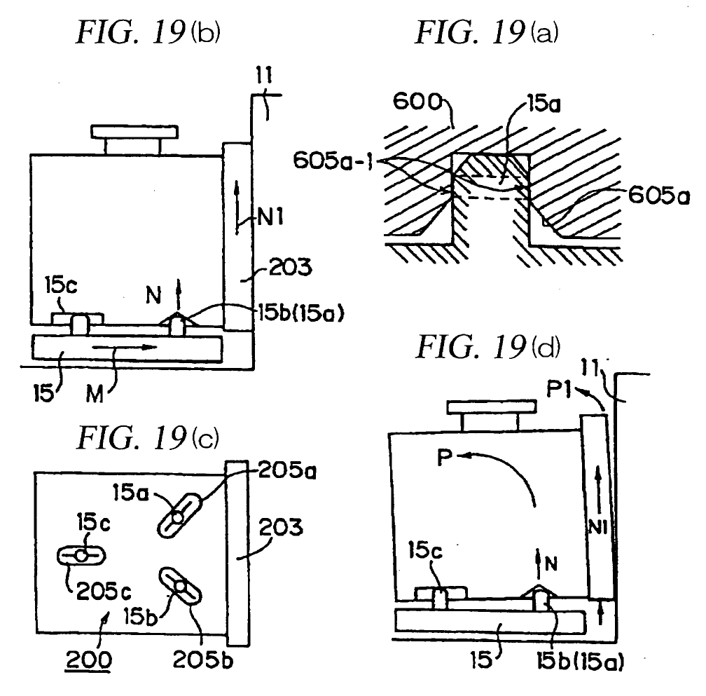

FIGS. 19(a), (b), (c), and (d) show a positioning member for the table of the pod cover removing-installing apparatus according to a fifth embodiment.

The positioning pins 15a-15c of the table 15 (see the table 105 of FIG. 21) are arranged as shown in FIG. 19(b). For this reason, when the table 15 moves in the direction of the arrow M, a force pushing up the pod 200 in the direction of the arrow N (N1) is generated in the V-shaped grooves 205a, 205c. However, no excessive force is produced by the V-shaped groove 205c which is parallel to the moving direction.

As a result, a rotation force around the positioning pin 15c in the direction of the arrow P (P1) is created in the pod 200 as shown in FIG. 19(d). Because of this, the top end of the pod 200 may be separated from the partition board 11, resulting in problems such as defective sealing.

In the fifth embodiment, because the vertical fixed side 605a-1 (605b-1, 605c-1) provided in the V-shaped groove 605a (605b, 605c) formed on the bottom surface of the pod 600 enables the pod 600 to come into contact with the vertical fixed side 15a-1 (15b-1, 15c-1) of the positioning pin 15a (15b, 15c) (a bonding posture corrective means), no force pushing the pod 600 upward is created even if the container is pushed in the horizontal direction.

A more detailed description is given of the pod 600 and the table 15 according to the fifth embodiment.

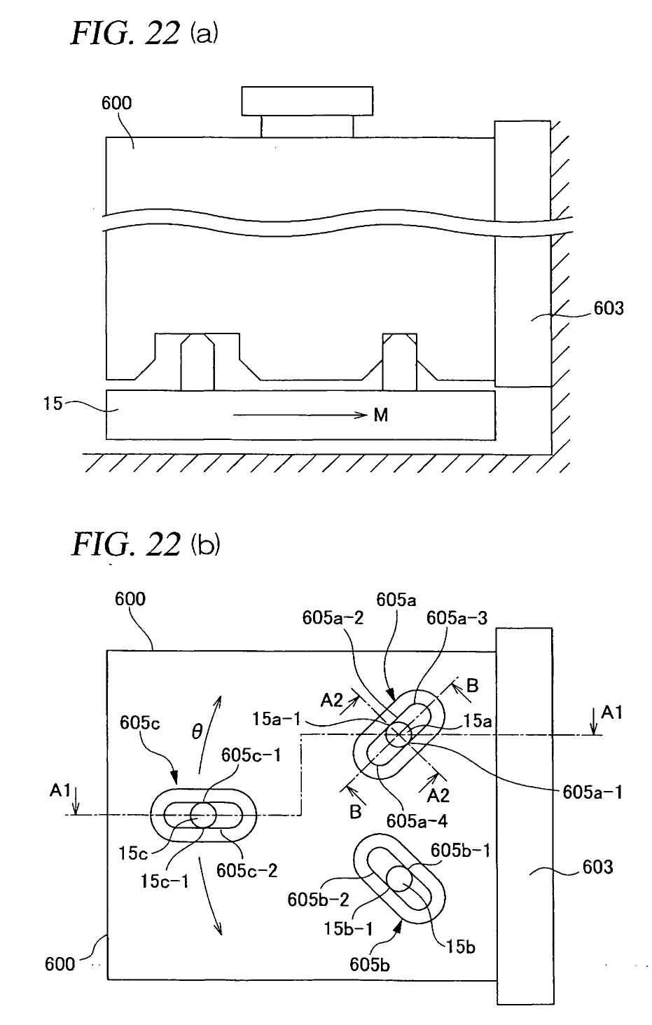

FIGS. 22(a) and 22(b) show the pod 600 and the table 15 according to the fifth embodiment of the present invention. FIG. 22(a) is a partial sectional view taken along line A1-A1 of FIG. 22(b). FIG. 22(b) is a bottom view.

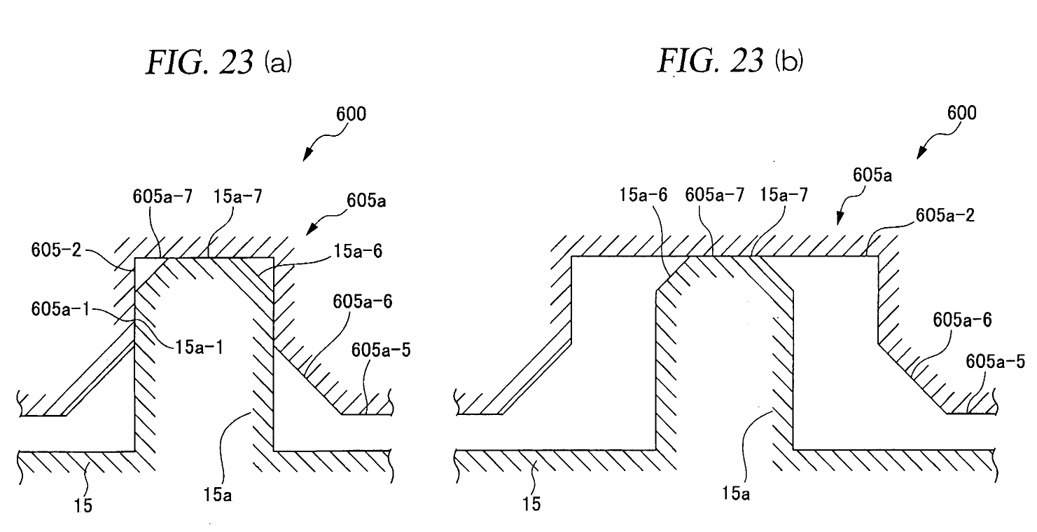

FIGS. 23(a) and 23(b) are sectional views showing a V-section groove 605a and a positioning pin 15a according to the fifth embodiment, which are engaged with each other. FIG. 23(a) is a sectional view taken along line A2-A2 of FIG. 22(b). FIG. 23(b) is a sectional view taken along line B-B of FIG. 22(b). It should be noted that FIG. 23(a) similar to FIG. 19(a) is shown for comparison.

As shown in FIG. 22(b), the pod 600 has three V-section groves 605a, 605b and 605c.

The V-section grooves 605a and 605b are arranged such that they depart from each other as they approach the cover 603 in a direction (arrow M) of the movement of the table 15. In contrast, the V-section groove 605c is arranged such that its longitudinal direction is in parallel with the direction of the movement of the table 15.

A description is typically given of the V-section groove 605a, omitting a description of the V-section grooves 605b and 605c which have a similar configuration.

As shown in FIGS. 23(a) and 23(b), the V-section groove 605a includes an oblong hole (recessed portion) 605a-2 and a slope 605a-6.

The oblong hole 605a-2 is a recessed portion of the V-section groove 605a in a vertical direction (perpendicular to the horizontal direction of the movement of the table 15). As shown in FIG. 22(b), the oblong hole 605a-2 has a parallel portion, and semicircular portions 605a-3 and 605a-4 at both ends of the oblong hole 605a-2.

As shown in FIGS. 23(a) and 23(b), the oblong hole 605a-2 has an inner wall serving as a fixed side 605a-1, which comes into contact with a positioning pin 15a.

The slope 605a-6, which starts from a bottom surface 605a-5 of the pod 600 and is provided around the thorough circumference of the oblong hole 605a-2, tapers with a constant angle of inclination.

As shown in FIGS. 22(a) and 22(b), the table 15 moves the pod 600 while it is placed on the table 15. The table 15 is set to move in a horizontal direction. The table 15 has three positioning (linking) pins 15a, 15b and 15c.

The positioning pins 15a, 15b and 15c are arranged on the table 15 such that they are in geometrical conformity with the V-section grooves 605a, 605b and 605c, respectively. The positioning pins 15a, 15b and 15c project from the table 15 such that their axes are vertically aligned with respect to the table 15. A description is typically given of the positioning pin 15a, omitting a description of the positioning pins 15b and 15c, which have the similar configuration.

As shown in FIGS. 23(a) and 23(b), the positioning pin 15a is a cylindrical member. The positioning pin 15a, whose diameter is substantially the same as the width of the oblong hole 605a, is engaged with the oblong hole 605a. As shown in FIG. 22(b), the diameter of the positioning pin 15a is substantially the same as those of the semicircular portions 605a-3 and 605a-4, which are located at both ends of the oblong hole 605a. In this way, it is possible to allow the positioning pin 15a to come into surface contact with the semicircles 605a-3 and 605a-4 so as to prevent damage to be imposed on them in case they collide with each other.

As shown in FIGS. 23(a) and 23(b), a guide portion 15a-6 is provided around a thorough circumference in the vicinity of an end portion of the positioning pin 15a. The guide portion 15a-6 is tapered as viewed in a cross section. The guide portion 15a-6 has an angle of inclination substantially the same as that of the slope 605a-6 of the V-section groove 605a. Accordingly, it is possible to slide the slope 605a-6 of the V-section groove 605a on the guide portion 15a-6 so as to guide the fixed side 605a-1 to the positioning pin 15a. In this way, it is possible to smoothly place the pod 600 on the table 15.

A description is next given of the operation of the pod 600 and the table 15.

As shown in FIGS. 22(a) and 22(b), an operator is allowed to place the pod 600 on the table 15 such that guide portions 15a-6, 15b-6 and 15c-6 of the positioning pins 15a-15c (see FIGS. 23(a) and 23(b) for 15a-6) and slopes 605a-6, 605b-6 and 605c-6 of the V-section grooves 605a-605c (see FIGS. 23(a) and 23(b) for 605a-6) come into contact with each other. Accordingly, the oblong holes 605a-2, 605b-2 and 605c-2 are guided to the positioning pins 15a-15c, so that the fixed sides 605a-1, 605b-1 and 605c-1 of the V-section grooves 605a-605c and fixed sides 15a-1, 15b-1 and 15c-1 of the positioning pins 15a-15c eventually come into contact with each other.

When the fixed side 15a-1 of the positioning pin 15a and the fixed side 605a-1 of the V-section groove 605a come in contact with each other (see FIG. 22(a)), and the fixed side 15b-1 of the positioning pin 15b and the fixed side 605b-1 of the V-section groove 605b come in contact with each other, the position of the pod 600 is determined in a back and forth direction, which corresponds to a direction of the movement of the table 15.

In addition, when the fixed side 15c-1 of the positioning pin 15c and the fixed side 605c-1 of the V-section groove 605c come into contact with each other, a rotational movement in a horizontal direction (see arrow θ in FIG. 22(b)) is restricted so as to perform positioning in the horizontal direction.

As shown in FIGS. 23(a) and 23(b), with respect to a vertical direction, a flat surface 15a-7 provided on an end of the positioning pin 15a and a flat surface 605a-7 of the oblong hole 605a come into contact with each other. The same is true of a combination of the positioning pin 15b and the oblong hole 605b-2 and another combination of the positioning pin 15c and the oblong hole 605c-2. In this way, the position of the pod 600 is determined in the vertical direction with respect to the table 15. Since these flat surfaces in surface contact receive the load of the pod 600, it is possible to prevent bottom surfaces 605a-5, 606b-5 and 605c-5 of the pod 600 from denting, increasing the durability of the pod 600.

When the cover 603 is removed or installed, the pod cover removing-installing apparatus can prevent the pod 600 from lifting as described above. When the diameter of a wafer increases, it is generally necessary to prepare a larger pod with a larger cover. This necessitates applying bigger force to the pod while the cover is removed or installed. Accordingly, it may be that the greater the diameter of wafer, the more likely the pod 600 tends to lift.

Since the positioning pins 15a-15c, which are oriented in the vertical direction perpendicular to the direction in which force is applied to the pad 600, are in contact with the fixed sides 605a-1, 605b-1 and 605c-1, respectively, the pod 600 according to this embodiment can efficiently prevent lifting described above.

### f. Sixth Embodiment

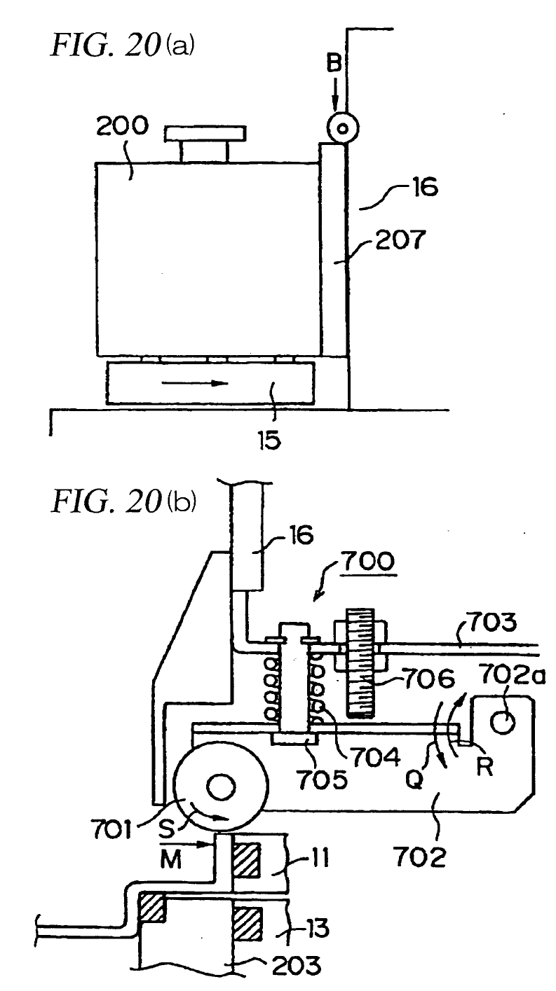

FIGS. 20(a) and (b) show a positioning member of the pod cover removing-installing apparatus according to a sixth embodiment.

The fifth embodiment cannot be applied to a pod 200 which has already been used. Modification of the types and the like is necessary to change such a pod. For this reason, the sixth embodiment is provided with a binding posture corrective mechanism 700 which corrects the linking position of the pod 200.

The binding posture corrective mechanism 700 is provided with a rotor 701 such as a bearing provided on the top and side of the door frame 16 connected to the cover frame 207 of the pod 200 and maintaining contact with the cover frame 207, a moving board 702 rotatively supporting the rotor 701 on the left end thereof and rotatively supported by the axis 702a at the upper right end, a linking member 705 which links the moving board 702 with a fixed board 703 so that the rotor 701 always presses the cover frame 207 with a spring 704 between them and regulates the counterclockwise rotation (arrow Q) of the moving board 702, a regulating member 706 provided on the fixed board 703 to regulate the clockwise rotation (arrow R) of the moving board 702, and the like.

The rotor 701 can not only freely move in the moving direction (arrow M) on the table 15 by its rotation, but can also freely move in the right angle direction of the arrow M by the rotation of the moving board 702. The rotor 701 is arranged so that it always presses the pod 200 by a spring 704. In addition, the movable range for the rotor 701 is limited via a movable board 702 to the minimum push-out position of the linking member 705 and the maximum push-out position of the regulating member 706.

Therefore, the top and the side of the pod 200 can be pressed in the linked position so that the pod 200 is held in a normal posture ready to be linked.

### g. Seventh Embodiment

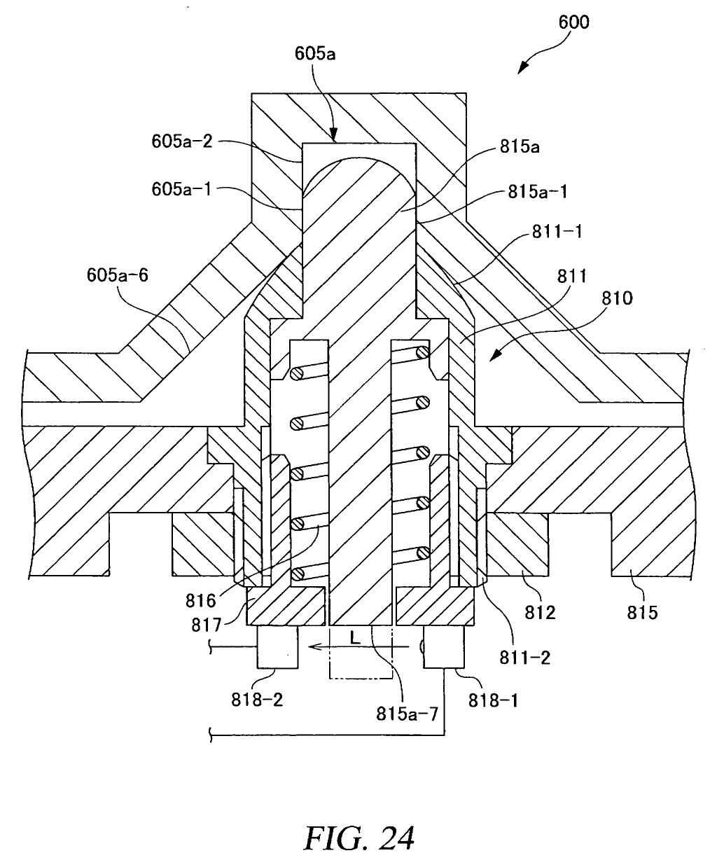

FIG. 24 is a sectional view showing a positioning pin 815a in contact with a V-section groove 605a of a pod 600 according to the seventh embodiment (see FIG. 23(a) for comparison).

In a cover removing-installing apparatus according to the seventh embodiment, the positioning pins 15a-15c according to the fifth embodiment are modified.

A movable table 815 for removing and installing a cover according to the present embodiment has three position adjusting devices 810. FIG. 24 depicts one of these three.

A position adjusting device 810 includes a base member 811, a positioning pin 811, a biasing member 816, a bottom cover 817 and an optical sensor 818.

The base member 811 is a cylindrical member that supports the positioning pin 815a movably in an axial direction of the pin 815a, namely in a vertical direction. The base member 811 has a guide portion 811-1 (a portion abutting with a slope of a V-section groove) that guides a fixed side 605a-1 to the positioning pin 815a. The guide portion 811-1 has a circular cross section, which abuts with a slope 605a-6 of a V-section groove 605a so as to guide the fixed side 605a-1.

The guide portion 811-1 determines the vertical position (perpendicular to the movement of the table 815) of a pod 900, while abutting with the slope 605a-6 of the V-section groove 605a after the guide portion 811-1 has guided the fixed side 605a-1 to the positioning pin 815a.

The base member 811, which has threads 811-2 on its outer circumference, is attached to the table 815 with a nut 812.

The arrangement of positioning pins 815a is geometrically similar to that of the positioning pins 15a-15c according to the fifth embodiment. A positioning pin 815 is movably supported by the base member 811 in a vertical direction. The positioning pin 815a has a top portion like a hemisphere and a light shielding portion 815a-7 at a lower portion.

When the positioning pin 815a projects from the base member 811, a bottom surface of the light shielding portion 815a-7 is configured to be flush with a bottom surface of the bottom cover 817. Accordingly, the light shielding portion 815a-7 projects with respect to the bottom cover 817 as shown with a two-dot chain line in FIG. 24 while the positioning pin 815a is forced to retract into the base member 811.

A compressive coil spring installed in the base member 811 is an example of the biasing member 816. The position of the biasing member 816 is determined in such a manner that the lowest portion of the biasing member 816 is supported by the bottom cover 817 and the highest portion abuts with an inner bottom surface of the positioning pin 815a. In this way, the biasing member 816 biases the positioning pin 815a vertically upward, which allows the positioning pin 815a to project from the base member 811.

The bottom cover 817 is a member to engage with the base member 811 by threads so as to cover a lower portion of the base member 811. The bottom cover 817 has a through hole that allows the light shielding portion 815a-7 to pass through.

The optical sensor 818 is a detector that has a light emitting device 818-1 and a light receiving device 818-2, which are disposed opposite to each other. The optical sensor 818 is disposed on the bottom surface of the bottom cover 817. When the light shielding portion 815a-7 of the positioning pin 815a does not project from the bottom surface of the bottom cover 817, the light receiving device 818-2 can receive light L emitted by the light emitting device 818-1. In contrast, when the light shielding portion 815a-7 projects from the bottom surface of the bottom cover 817, the light receiving device 818-2 cannot receive the light L, which is obstructed by the light shielding portion 815a-7. In this way, the optical sensor 818 detects whether the light shielding portion 815a-7 projects from the bottom surface of the bottom cover 817.

The optical sensor 818 is electrically connected with the controller (see FIG. 8), to which the optical sensor 818 transmits a detection signal.

A description is given of operation of the pod 600 and the table 815.

When an operator places the pod 600 on the table 815, the operator is merely requested to arrange the pod 600 such that the guide portion 811-1 abuts with the slope 605a-6 of the V-section groove 605a. Accordingly, the oblong hole 605a-2 is guided to the positioning pin 815a, so that the fixed side 605a-1 eventually comes into contact with the fixed side 815a-1 of the positioning pin 815a.

While the guide portion 811-1 is guiding the fixed side 605a-1 to the positioning pin 815a, the positioning pin 815a is forced to retract into the base member 811, because the slope 605a-6 of the V-section groove 605a thrusts the positioning pin 815a.

Accordingly, the light shielding portion 815a-7 of the positioning pin 815a projects from the bottom surface of the bottom cover 817. The controller, which receives a signal from the optical sensor and determines that the pod 600 is not properly placed on the table 815, maintains the table 815 at rest without activating the container moving motor (see FIG. 8).

When the guide portion 811-1 has guided the fixed side 605a-1, the positioning pin 815a is biased by the biasing member 816 to project from the base member 811 (see FIG. 24). The horizontal position of the pod 600 with respect to the table 815 is determined by the positioning pin 815a.

In parallel, the vertical position of the pod 600 is determined by the guide portion 811-1 that abuts with the slope 605a-6 of the V-section groove 605a.

Under this situation, the bottom surface of the light shielding portion 815a-7 of the positioning pin 815a moves upward to be flush with the bottom surface of the bottom cover 817. Accordingly, since the controller determines that the pod 600 has been properly placed on the table 815, receiving a signal from the optical sensor 818, it activates the container moving motor so as to advance the table 815.

In this connection, it may be possible to determine whether the pod 600 is properly placed on the table 815 by the following alternatives.

An alternative introduces an optical sensor that is provided on the table 815 to measure the distance between the top surface of the table 815 and the bottom surface of the pod 600 so as to check the correct placement of the pod 600. For this purpose, it is necessary for the optical sensor to maintain the accuracy substantially within 2 mm, which may be disadvantageous in terms of required accuracy for installation and maintenance.

Another alternative introduces a sensor to detect the weight of the pod 600, such as a pressure sensor, which is attached to the positioning pins 815a-815c so as to check the placement of the pod 600. This method has disadvantages as follows: Since the pressure sensor has relatively large detection error, it may be a cause for the malfunction of the table 815. In addition, the weight of the pod 600 has variations according to objects contained in the pod 600.

In contrast, the above-mentioned embodiment of the present invention, which determines whether the positioning pin 815a projects from the bottom cover 817 so as to check whether the pod 600 is properly placed on the table 815, is almost immune to a detection error. In addition, it is possible to maintain a movement stroke of the positioning pin 815a to be substantially the same as the depth of the oblong hole 605a-1. This indicates that since it is possible to select a greater value, ex. 5 mm for the movement stroke corresponding to the amount of projection of the positioning pin 815a, this embodiment does not require high accuracy for installation, realizing easy maintenance.

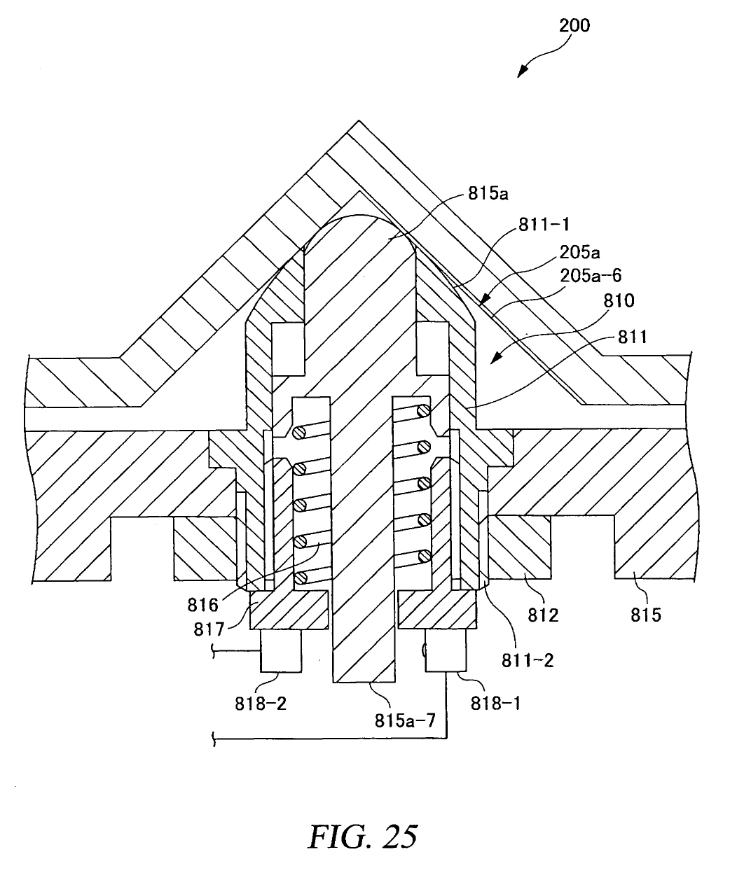

FIG. 25 is a sectional view showing a positioning pin 815a of the cover removing-installing apparatus engaging with a V-section groove 205a of a pod 200 according to the seventh embodiment (see FIG. 23(a) for comparison).

The conventional pod 200 does not have oblong holes 605a-2, 605b-2 and 605c-2 (see FIG. 22(b)), which are introduced into the pod 600 according to the present invention. However in the case of the conventional pod 200, a slope 205a-6 of the V-section groove 205a thrusts the positioning pin 815a to retract into the base member 811. Since the guide portion 811-1 (a portion abutting with a slope of a V-section groove) abuts with the slope 205a-6 of the V-section groove 205a accordingly, the horizontal and vertical directions of the pod 200 can be determined.

It should be noted that the controller controls the movement of the table 815 regardless of reception of a signal from the optical sensor 818.

In this way, it is possible to apply the cover removing-installing apparatus according to the present embodiment to a conventional pod 200.

As described above, determining whether the pod 600 is properly placed on the table 815, the cover removing-installing apparatus according to the seventh embodiment can safely advance the table 815.

In addition, the cover removing-installing apparatus according to the seventh embodiment can be applied to both the pod 600 that has the oblong holes 605a-2, 605b-2 and 605c-2 and the conventional pod 200 without these oblong holes.

### h. Eighth Embodiment

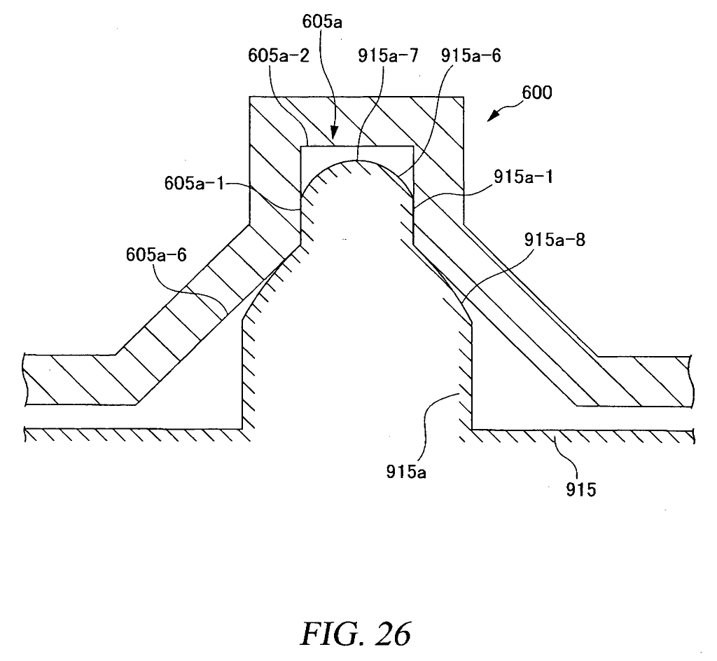

FIG. 26 is a sectional view showing a positioning pin 915a engaging with a V-section groove 605a of a pod 600 (see FIG. 23(a) for comparison).

Three positioning pins 915a are disposed on a table 915 of a cover removing-installing apparatus similarly with the positioning pins 15a-15c of the fifth embodiment.

A positioning pin 915a has a two-part configuration, an upper portion 915a-7 and a lower portion 915a-8. A guide portion 915a-6 is provided on an end portion of the upper portion 915a-7. The guide portion 915a-6 having a circular cross section abuts with a slope 605a-6 of the V-section groove 605a so as to guide a fixed side 605a-1 of the V-section groove 605a to a fixed side 915a-1 of the fixed pin 915a. In addition, a cross section of the lower portion 915a-8 (a portion abutting with a slope of a V-section groove) is circular.

When the fixed side 915a-1 of the positioning pin 915a and the fixed side 605a-1 of the V-section groove 605a are in contact with each other, the position of the pod 600 is determined with respect to the table 915 in the similar manner to the seventh embodiment.

The horizontal position of the pod 600 is determined by the fixed side 915a-1 of the positioning pin 915a and the fixed side 605a-1 of the oblong hole 605a-2. Similarly, the vertical position of the pod 600 is determined by the lower portion 915a-8 of the positioning pin 915a and the slope 605a-6 of the V-section groove 605a, which abut with each other.

As described above, the cover removing-installing apparatus according to the present embodiment can determine the position of the pod 600 with the positioning pin 915a whose top surface is not flat but circular.

### i. Ninth Embodiment

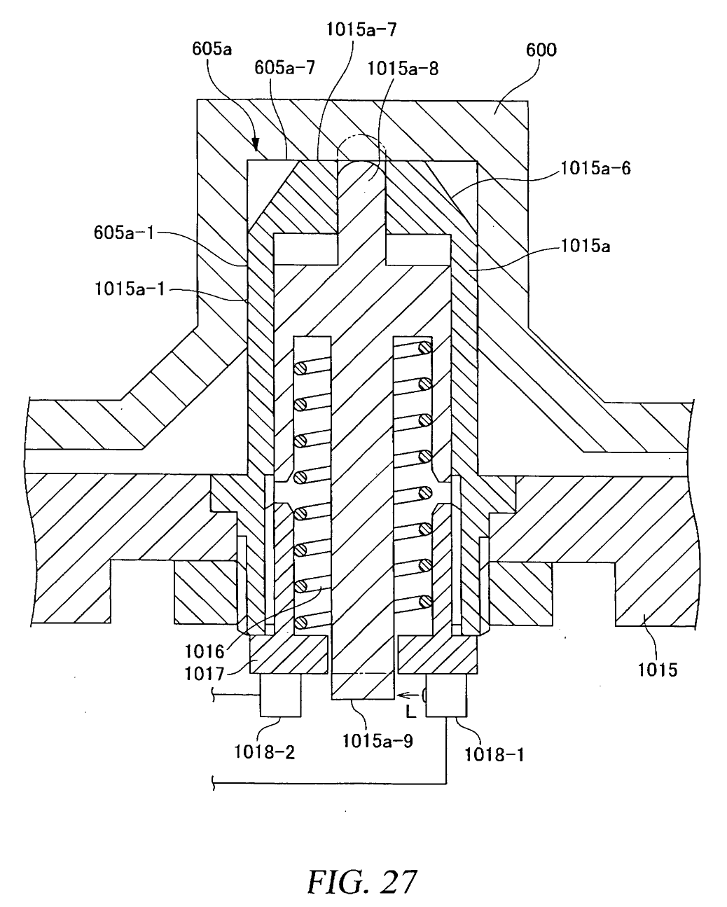

FIG. 27 is a sectional view showing a positioning pin 1015a engaging with a V-section groove 605a of a pod 600 (see FIG. 23(a) for comparison).

The positioning pin 1015a has a detection pin 1015a-8 that is vertically movable. The positioning pin 1015a includes a biasing member 1016 and an optical sensor 1018, which are similar to the biasing member 816 and the optical sensor 818 of the seventh embodiment, respectively.

The positioning pin 1015a is biased vertically upward by the biasing member 1016. When a pod 600 is not placed on a table 1015, the detection pin 1015a-8 projects with respect to a flat portion 1015a-7 as shown by a two-dot chain line in FIG. 27 and the bottom surface of a light shielding portion 1015a-9 is adjusted to be in flush with the bottom surface of a bottom cover 1017.

When the pod 600 is placed on the table 1015 and a fixed side 605a-1 is guided by a guide portion 1015a-6, the pod 600 is properly placed on the table 1015. Accordingly, the flat portion 1015a-7 of the positioning pin 1015a comes into surface contact with a flat surface 605a-7 of the bottom portion of the pod 600. Under this configuration, the flat surface 605a-7 thrusts the detection pin 1015a-8 vertically downward. Accordingly as shown in FIG. 27, the detection pin 1015a-8 is depressed into the inside of the positioning pin 1015a. Since the light shielding portion 1015a-9 simultaneously projects from the bottom cover 1017a, a light receiving device 1018-2 cannot receive light L emitted by a light emitting device 1018-1. In this way, the pod cover removing-installing apparatus according to the embodiment can detect whether the pod 600 has been properly placed on the table 1015.

As described above, receiving a signal from a detector with the light emitting device 1018-1 and the light receiving device 1018-2, the cover removing-installing apparatus according to the embodiment can detect whether the flat portion 1015a-7 of the positioning pin 1015a has come into surface contact with the flat surface 605a-7 of the bottom portion of the pod 600. Accordingly, the cover removing-installing apparatus can detect whether the pod 600 has been properly placed on the table 1015.

It should be noted that the cover removing-installing apparatus can alternatively employ a pressure sensor that is provided on the flat surface 1015a-7 of the positioning pin 1015a in lieu of the light emitting device 1018-1 and the light receiving device 1018-2. In this case, the cover removing-installing apparatus determines whether the pod 600 is placed on the table 1015 based on a change in pressure that results from the surface contact between the flat portion 1015a-7 of the positioning pin 1015a and the flat surface 605a-7 of the pod 600. In this way, the cover removing-installing apparatus can provide more confident detection whether the pod 600 has been properly placed on the table 1015.

### j. Modification

The present invention is not limited to the above-described embodiments and can be varied or modified in various ways. Such variations and modifications are within the scope of equivalency of the present invention.

For example, although the cover securing means was described in FIG. 7 using a stretch member 63 by way of example, a modified type having a broken part in the positioning pin 14a (14b) to mechanically change the diameter of the positioning pin 14a (14b) can be used for securing the pins in the pin holes.

Obviously, numerous modifications and variations of the present invention are possible in light of the above teachings. It is therefore to be understood that, within the scope of the appended claims, the invention may be practiced otherwise than as specifically described herein.

What is claimed is:

1. A pod cover removing-installing apparatus to remove and install a cover for an opening of a pod, an inside of which is kept extremely clean, by causing the cover to engage a door for an opening of a high cleanliness room, while maintaining high cleanliness of the pod and the room by closely attaching circumferences of the two openings, the pod cover removing-installing apparatus comprising:
a movable pod table having the pod installed thereon; and
a linking pin provided on the movable pod table,
wherein the linking pin is substantially vertically aligned with respect to a moving direction of the pod table and comes in contact with a fixed side which is substantially vertically aligned with respect to the moving direction of the pod table, and the fixed side is provided in a V-section groove provided on a bottom of the pod.

2. The pod cover removing-installing apparatus according to claim 1, wherein
the moving direction of the pod table is set in a horizontal direction,
an axis of the linking pin is vertically aligned with the horizontal direction,
the fixed side is a vertical inner wall provided in a recessed portion of the V-section groove, and
the linking pin engages with the vertical inner wall.

3. The pod cover removing-installing apparatus according to claim 2, wherein
the linking pin has a first flat surface on an end portion thereof,
the recessed portion has a second flat surface on a bottom portion thereof, and
the first flat surface and the second flat surface come into surface contact with each other so as to determine a vertical position of the pod.

4. The pod cover removing-opening apparatus according to claim 3, further comprising a detector that detects an occurrence of surface contact between the first flat surface and the second flat surface.

5. The pod cover removing-installing apparatus according to claim 2, wherein
the linking pin has an abutting portion that comes into contact with a slope of the V-section groove so as to determine a vertical position of the pod.

6. The pod cover removing-installing apparatus according to claim 1, wherein
the moving direction of the pod table is set in a horizontal direction,
the linking pin has a guide portion on an end portion thereof, the guide portion being sectionally configured to be tapered, and
the guide portion allows the fixed side to be guided into contact with the linking pin.

7. The pod cover removing-installing apparatus according to claim 1, wherein
the moving direction of the pod table is set in a horizontal direction,
the linking pin has a guide portion on an end portion thereof, the guide portion being sectionally configured to be circular, and
the guide portion allows the fixed side to come into contact with the linking pin.

8. The pod cover removing-installing apparatus according to claim 1, further comprising a guide portion, a base member and a biasing member, wherein
the guide portion abuts with a slope of the V-section groove so as to guide the fixed side to the linking pin,
the base member supports the linking pin movably in an axial direction thereof, and
the biasing member biases the linking pin, wherein
the slope of the V-section groove thrusts the linking pin into the base member while the guide portion is guiding the fixed side to the linking pin, and
the biasing member urges the linking pin to project from the base member when the guide portion finishes guiding the fixed side to the linking pin.

9. The pod cover removing-installing apparatus according to claim 8, further comprising a detector that detects the projection of the linking pin from the base member.

10. The pod cover removing-installing apparatus according to claim 8, wherein the guide portion is an abutting portion that abuts with the slope of the V-shaped groove so as to determine a vertical position of the pod after the guide portion finishes guiding the fixed side to the linking pin.

11. A pod with high cleanliness having a cover for an opening thereof, the cover being removed and installed by a pod cover removing-installing apparatus when the cover is engaged with a door for an opening of a room with high cleanliness, while high cleanliness of the pod and the room is maintained by closely attaching circumferences of the two openings, the pod comprising:
a V-section groove provided on a bottom of the pod,
wherein the V-section groove has a fixed side substantially vertically aligned with respect to a moving direction of a movable table of the pod cover removing-installing apparatus, and
wherein the fixed side comes into contact with a linking pin that is substantially vertically aligned with respect to the moving direction and provided on the movable pod table.

12. The pod according to claim 11, wherein
the moving direction of the movable pod table is set in a horizontal direction,
the fixed side is a vertical inner wall provided in a recessed portion of the V-section groove, and
the vertical inner wall engages with the linking pin.

13. The pod according to claim 11, wherein
the recessed portion has a first flat surface on a bottom portion thereof,
the linking pin has a second flat surface on an end portion thereof, and
the first flat surface and the second flat surface come into surface contact with each other so as to determine a vertical position of the pod.

14. A system for removing and installing a cover of a pod, comprising:
a pod that is internally kept clean; and
a cover removing-installing unit that removes and installs a cover for an opening of the pod by causing the cover to engage a door for an opening of a high cleanliness room, while maintaining high cleanliness of the pod and the room by closely attaching circumferences of the two openings,
wherein the cover removing-installing unit includes:
a movable table; and
a linking pin that is substantially vertically aligned with respect to a moving direction of the movable table and provided on the movable table,
wherein the pod has a fixed side that is substantially vertically aligned with respect to the direction of the movable table and is provided in a V-section groove provided on a bottom of the pod, and
wherein the fixed side comes into contact with the linking pin.
